(19) United States
(12) Patent Application Publication
(10) Pub. No.: US 2026/0239958 A1
(43) Pub. Date: Aug. 13, 2026

(54) PACKAGE LID STRUCTURE AND METHODS OF TESTING THE SAME

(71) Applicant: Taiwan Semiconductor Manufacturing Company Limited, Hsinchu (TW)

(72) Inventors: Yi-Hsuan WU, Hsinchu (TW); Wei-Kong SHENG, Chu-Nan (TW); Lipu Kris CHUANG, Hsinchu (TW); Pu WANG, Hsinchu (TW); Wensen HUNG, Zhubei City (TW); Yen-Ming CHEN, Chu-Pei City (TW)

(21) Appl. No.: 19/049,252

(22) Filed: Feb. 10, 2025

(51) Int. Cl. H01L 23/367; H01L 21/50; H01L 23/00; H01L 23/538; H01L 25/07

(52) U.S. Cl. CPC H10W 40/22; H10W 70/611; H10W 90/401; H10W 95/00; H10W 72/07332; H10W 90/00; H10W 90/734

(57) ABSTRACT

A packaging structure may be formed by: providing a composite package including at least one semiconductor die and a die frame; attaching the composite package to a packaging substrate to form a bonded assembly; providing a lid structure including a bottom plate portion, a top plate portion, a sidewall frame portion laterally surrounding a cavity located between the bottom plate portion and the top plate portion, and solid block portions vertically extending between the bottom plate portion and the top plate portion; and attaching the lid structure to the bonded assembly such that a thermal interface material (TIM) layer is interposed between the at least one semiconductor die and the bottom plate portion. The solid block portions do not have any areal overlap with the at least one semiconductor die in a plan view along a vertical direction.

### BACKGROUND

Semiconductor devices generate heat during operation, requiring efficient thermal dissipation to ensure performance and reliability. Proper application of a thermal interface material (TIM) layer between semiconductor dies and a lid structure is desired to ensure that the heat generated from the semiconductor dies is effectively transferred to the lid structure, which functions as a radiator for the heat. X-ray inspection is typically used to determine whether the TIM layer has been properly applied and covers the necessary areas without voids or defects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of an exemplary structure after formation of a through interposer via (TIV) structures over a first carrier wafer according to an embodiment of the present disclosure.

FIG. 2A is a vertical cross-sectional view of the exemplary structure after attaching local silicon interconnect (LSI) bridges to the first carrier wafer according to an embodiment of the present disclosure. FIG. 2B is a top-down view of the exemplary structure of FIG. 2A. FIG. 2C is an enhanced vertical cross-sectional view of an LSI bridge in the exemplary structure of FIGS. 2A and 2B.

FIG. 3 is a vertical cross-sectional view of the exemplary structure after formation of an interposer-level molding compound material layer according to an embodiment of the present disclosure.

FIG. 4 is a vertical cross-sectional view of the exemplary structure after formation of an interposer-level molding compound matrix according to an embodiment of the present disclosure.

FIG. 5 is a vertical cross-sectional view of the exemplary structure after formation of a first redistribution structure according to an embodiment of the present disclosure.

FIG. 6A is a vertical cross-sectional view of the exemplary structure after attaching semiconductor dies to the first redistribution structure according to an embodiment of the present disclosure. FIG. 6B is a top-down view of a unit area of the exemplary structure of FIG. 6A. The vertical plane A-A′ is the cut plane of the vertical cross-sectional view of FIG. 6A.

FIG. 7 is a vertical cross-sectional view of the exemplary structure after formation of die-side underfill material portions according to an embodiment of the present disclosure.

FIG. 8 is a vertical cross-sectional view of the exemplary structure after formation of a die-level molding compound matrix according to an embodiment of the present disclosure.

FIG. 9 is a vertical cross-sectional view of the exemplary structure after attaching a second carrier wafer to a reconstituted wafer and detaching the first carrier wafer according to an embodiment of the present disclosure.

FIG. 10 is a vertical cross-sectional view of the exemplary structure after formation of a second redistribution structure according to an embodiment of the present disclosure.

FIG. 11A is a vertical cross-sectional view of a composite package according to an embodiment of the present disclosure. FIG. 11B is a top-down view of the composite package of FIG. 11A. The vertical plane A-A′ is the cut plane of the vertical cross-sectional view of FIG. 11A.

FIG. 12 is a vertical cross-sectional view of a bonded assembly comprising the composite package and a packaging substrate according to an embodiment of the present disclosure.

FIG. 13A is a vertical cross-sectional view of a packaging structure formed by attaching a lid structure to the bonded assembly according to an embodiment of the present disclosure. FIG. 13B is a horizontal cross-sectional view of the packaging structure along the horizontal plane B-B′ of FIG. 13A, in which components of the composite package are illustrated in dotted lines. The vertical plane A-A′ in FIG. 13B is the cut plane of the vertical cross-sectional view of FIG. 13A. FIG. 13C is a horizontal cross-sectional view of the packaging structure along the horizontal plane C-C′ of FIG. 13A. The vertical plane A-A′ in FIG. 13B is the cut plane of the vertical cross-sectional view of FIG. 13A. FIG. 13D is a vertical cross-sectional view of the packaging structure along the vertical plane D-D′ of FIGS. 13B and 13C. FIG. 13E is a vertical cross-sectional view of the packaging structure along the vertical plane E-E′ of FIGS. 13B and 13C.

FIG. 14A is a vertical cross-sectional view of a first alternative configuration of the packaging structure according to an embodiment of the present disclosure. FIG. 14B is a horizontal cross-sectional view of the first alternative configuration of the packaging structure along the horizontal plane B-B′ of FIG. 14A, in which components of the composite package are illustrated in dotted lines. The vertical plane A-A′ in FIG. 14B is the cut plane of the vertical cross-sectional view of FIG. 14A.

FIG. 15A is a vertical cross-sectional view of a second alternative configuration of the packaging structure according to an embodiment of the present disclosure. FIG. 15B is a horizontal cross-sectional view of the second alternative configuration of the packaging structure along the horizontal plane B-B′ of FIG. 15A, in which components of the composite package are illustrated in dotted lines. The vertical plane A-A′ in FIG. 15B is the cut plane of the vertical cross-sectional view of FIG. 15A.

FIG. 16A is a vertical cross-sectional view of a third alternative configuration of the packaging structure according to an embodiment of the present disclosure. FIG. 16B is a horizontal cross-sectional view of the third alternative configuration of the packaging structure along the horizontal plane B-B′ of FIG. 16A, in which components of the composite package are illustrated in dotted lines. The vertical plane A-A′ in FIG. 16B is the cut plane of the vertical cross-sectional view of FIG. 16A.

FIG. 17A is a vertical cross-sectional view of a fourth alternative configuration of the packaging structure according to an embodiment of the present disclosure. FIG. 17B is a horizontal cross-sectional view of the fourth alternative configuration of the packaging structure along the horizontal plane B-B′ of FIG. 17A, in which components of the composite package are illustrated in dotted lines. The vertical plane A-A′ in FIG. 17B is the cut plane of the vertical cross-sectional view of FIG. 17A.

FIG. 18A is a vertical cross-sectional view of a fifth alternative configuration of the packaging structure according to an embodiment of the present disclosure. FIG. 18B is a horizontal cross-sectional view of the fifth alternative configuration of the packaging structure along the horizontal plane B-B′ of FIG. 18A, in which components of the composite package are illustrated in dotted lines. The vertical plane A-A′ in FIG. 18B is the cut plane of the vertical cross-sectional view of FIG. 18A.

FIG. 19A is a vertical cross-sectional view of a sixth alternative configuration of the packaging structure according to an embodiment of the present disclosure. FIG. 19B is a horizontal cross-sectional view of the sixth alternative configuration of the packaging structure along the horizontal plane B-B′ of FIG. 19A, in which components of the composite package are illustrated in dotted lines. The vertical plane A-A′ in FIG. 19B is the cut plane of the vertical cross-sectional view of FIG. 19A.

FIG. 20 illustrates an exemplary X-ray apparatus during testing of a packaging structure according to an embodiment of the present disclosure.

FIG. 21A-21G are schematic representations of various X-ray images that may be obtained upon testing of a packaging structure of the present disclosure.

FIG. 22 is a first flowchart illustrating steps for manufacturing a packaging structure according to an embodiment of the present disclosure.

FIG. 23 is a second flowchart illustrating steps for testing a packaging structure according to an embodiment of the present disclosure.

### DETAILED DESCRIPTION

The following disclosure provides many different embodiments, or examples, for implementing various features of the provided subject matter. Specific examples of components and arrangements are described below to clarify the present disclosure. These are merely examples, and are not limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe geometrical features among elements as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Semiconductor devices produce heat during operation, and effective cooling of the semiconductor devices is desired to prevent degradation of the semiconductor devices and to maintain the performance level and the reliability. Proper application of a thermal interface material (TIM) layer between the semiconductor dies and a lid structure is an important process for ensuring effective cooling of the semiconductor dies. The TIM layer transfers the semiconductor dies to the lid structure, which functions as a radiator. To ensure that the TIM layer is applied correctly and free of voids or defects, X-ray inspection is commonly utilized as a part of the quality control process. X-ray imaging is less effective in instances in which a thin TIM layer is examined through a thick metal portion, as the resulting image contrast is reduced. Conversely, reducing the metal thickness improves X-ray inspection but compromises thermal dissipation.

Embodiments of the present disclosure are directed to a lid structure for semiconductor packages that is configured to provide enhanced heat dissipation while allowing X-ray inspection of key areas of a TIM layer. The lid structure of the present disclosure comprises a bottom plate portion that contacts a top surface of the TIM layer, a top plate portion that is vertically spaced from the bottom plate portion, a sidewall frame portion that laterally encloses a cavity located between the bottom plate portion and the top plate portion, and solid block portions located within the sidewall frame and located at corner regions of the lid structure that are located entirely outside areas of, i.e., do not have any areal overlap with, the semiconductor devices in a plan view. X-ray may penetrate through the top plate portion and the bottom plate portion in areas in which the solid block portions are not present. The locations of the solid block portions are selected such that the solid blocks do not overlap with the semiconductor dies along the path of the X-ray beam. Thus, examination of the region of the TIM layer having an areal overlap with the semiconductor dies is possible.

The solid block portions of the lid structure may be located in the corner regions of the lid structure, and function as thermal mass structures that store heat and radiates heat to the ambient environment. The cavity between the bottom plate portion and the top plate portion reduces the amount of the metallic material that the X-rays needs to pass through during inspection of the TIM layer, and directs the heat flow in the bottom plate portion of the lid structure along radial directions. Thus, the cavity reduces the amount of metallic material that blocks the X-rays within the area of inspection for the TIM layer, and improves the efficiency of inspection of the TIM layer. The solid block portions of the lid structure enhance heat dissipation, and functions as heat sinks for the heat that propagates radially outward within the bottom plate portion and as radiators for the heat that accumulates therein. Thus, the presence of solid block portions in non-overlapping areas outside the areas of the semiconductor dies enables X-ray inspection of the semiconductor die areas, and improves heat dissipation from the corner regions of the package structure. Various configurations for the lid structure and threaded fasteners may be used, which are now described with reference to accompanying figures.

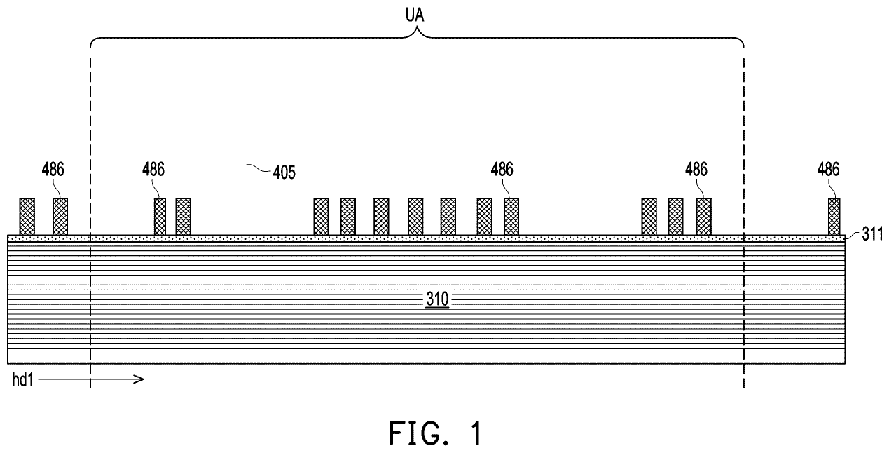

Referring to FIG. 1, an exemplary structure according to an embodiment of the present disclosure is illustrated. The structure includes a first carrier wafer 310. The first carrier wafer 310 may include an optically transparent substrate such as a glass substrate or a sapphire substrate, or may comprise a semiconductor substrate such as a silicon substrate. The diameter of the first carrier wafer 310 may be in a range from 150 mm to 450 mm, although lesser and greater diameters may be used. The thickness of the first carrier wafer 310 may be in a range from 500 microns to 2,000 microns, although lesser and greater thicknesses may also be used. Alternatively, the first carrier wafer 310 may be provided in a rectangular panel format. A first adhesive layer 311 may be applied to a front-side surface of the first carrier wafer 310. In one embodiment, the first adhesive layer 311 may be a light-to-heat conversion (LTHC) layer. Alternatively, the first adhesive layer 311 may include a thermally decomposing adhesive material.

A two-dimensional repetition of a unit via assembly may be formed over a first carrier wafer 310. Each instance of the unit via assembly may be formed within a respective unit area UA having a rectangular area. Multiple instances of the unit via assembly may be repeated along a first horizontal direction hd1 and along a second horizontal direction hd2 that is perpendicular to the first horizontal direction hd1. The unit area UA corresponds to the area of an interposer die to be subsequently formed. For example, each unit area UA may have a rectangular shape having a first side length along the first horizontal direction hd1 and having a second side length along the second horizontal direction hd2. The first side length may be the length of a pair of first sides of the rectangular shape. The second side length may be the length of a pair of second sides of the rectangular shape. The first side length is herein referred to as a first die lateral dimension dld1. The second side length is herein referred to as a second die lateral dimension dld2. Each of the first die lateral dimension dld1 and the second die lateral dimension dld2 may be independently in a range from 300 microns to 6 cm, although lesser and greater dimensions may also be used.

Generally, the TIV structures 486 may be formed over the first adhesive layer 311 by deposition and patterning of a conductive material, or by transfer from above another carrier wafer. In an illustrative example, a sacrificial matrix layer (not shown) may be formed over the first adhesive layer 311. The sacrificial matrix layer comprises a sacrificial material such as amorphous carbon, diamond-like carbon (DLC), a semiconductor material (such as amorphous silicon or a silicon-germanium alloy), or a dielectric material such as silicate glass or organosilicate glass. The thickness of the sacrificial matrix layer may be in a range from 3 microns to 60 microns, although lesser and greater thicknesses may also be used. A photoresist layer (not shown) may be applied over the sacrificial matrix layer. The photoresist layer may be lithographically pattered to form openings having a same pattern as the TIV structures 486 to be subsequently formed in a top-down view. An anisotropic etch process may be formed to transfer the pattern of the openings in the photoresist layer. Cylinder cavities may be formed through the sacrificial matrix layer underneath the openings in the photoresist layer. The photoresist layer may be removed for example, by ashing. At least one conductive material, such as at least one metallic material, may be deposited in the cylindrical cavities. For example, the at least one conductive material may comprise a conducive metallic barrier material (such as TiN, TaN, WN, or MoN) and a metallic fill material (such as W, Ti, Ta, Mo, Ru, Co, etc.). Excess portions of the at least one conductive material may be removed from above the horizontal plate including the sacrificial matrix layer. Remaining portions of the at least one conductive material that fill the cylindrical cavities comprise the TIV structures 486. Subsequently, the sacrificial matrix layer may be removed selectively to the TIV structures 486 and selectively to the first adhesive layer 311.

Alternatively, at least one conductive material layer may be deposited as a blanket material layer, i.e., as an un-patterned material layer having a uniform thickness throughout. For example, the at least one conductive material layer may comprise a conducive metallic barrier material (such as TiN, TaN, WN, or MoN) and a metallic fill material (such as W, Ti, Ta, Mo, Ru, Co, etc.). The thickness of the at least one conductive material layer may be in a range from 3 microns to 60 microns, although lesser and greater thicknesses may also be used. A photoresist layer (not shown) may be applied over the at least one conductive material layer. The photoresist layer may be lithographically patterned to form discrete photoresist material portions having a same pattern as the TIV structures 486 to be subsequently formed in a top-down view. An anisotropic etch process may be formed to transfer the pattern of the discrete photoresist material portions through the at least one conductive material layer. Patterned portions of the at least one conductive material layer comprise the TIV structures 486.

In a further alternative embodiment, the TIV structures 486 may be formed on another carrier wafer, and may be attached to the top surface of the first adhesive layer 311. The TIV structures 486 may be subsequently detached from the additional carrier wafer.

In one embodiment, the pattern of the TIV structures 486 within each unit area UA may be a pattern that is derived from a rectangular periodic array having a first pitch along the first horizontal direction hd1 and having a second pitch along the second horizontal direction hd2 by omitting a subset of the TIV structures 486. Specifically, omission of the subset of the TIV structures 486 may be made such that two rectangular corner regions are free of the TIV structures 486 and at least one center region is free of the TIV structures 486. The at least one center region corresponds to at least one area in which at least one local silicon interconnect (LSI) bridge is to be positioned. In one embodiment, each of the TIV structures 486 comprises a metallic via structure.

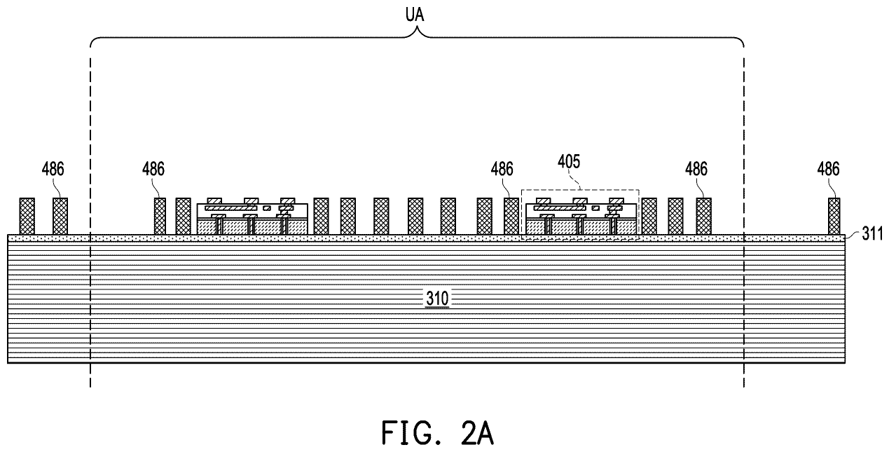

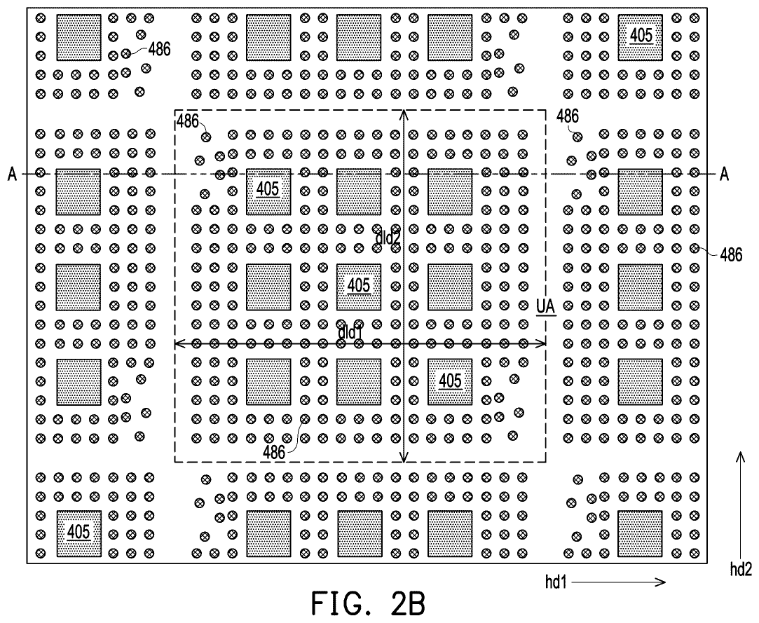

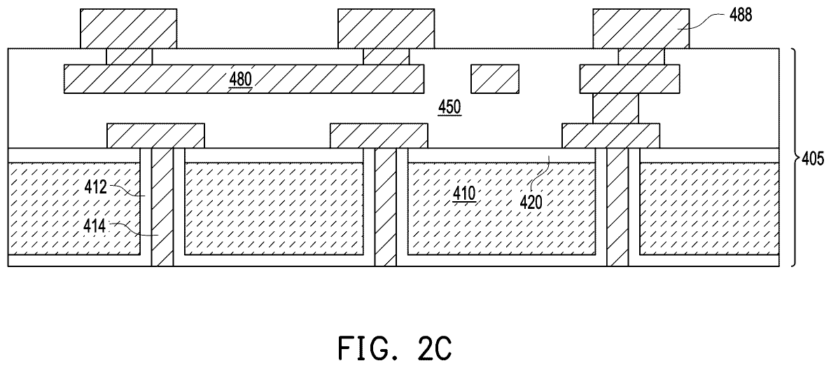

Referring to FIG. 2A-2C, a plurality of local silicon interconnect (LSI) bridges 405 may be provided. Each LSI bridge 405 includes a silicon substrate 410 (as thinned and diced during manufacturing of the local silicon interconnect bridge 405), through-silicon via structures 414 vertically extending through the silicon substrate 410, through-substrate openings that vertically extend through the silicon substrate 410, a dielectric liner 412 that provides electrical isolation for the through-silicon via structures 414, backside dielectric material layer 420, and metal interconnect structures 480 located in dielectric material layers 450 and electrically connected to the through-silicon via structures 414 and/or electrically connected to one another. Metal pads, which are herein referred to as LSI metal pads 488, may be provided on the topmost metal interconnect structures 480.

The LSI bridges 405 may be placed within openings in the arrays of the TIV structures 486 on the top surface of the first adhesive layer 311. Generally, a pick and place tool may be used to place at least one LSI bridge 405 within each unit area UA. At least one local silicon interconnect (LSI) bridge 405 may be placed within each unit area UA of repetition using the pick and place tool. In one embodiment, a plurality of LSI bridges 405 may be placed within each unit area UA of repetition using the pick and place tool.

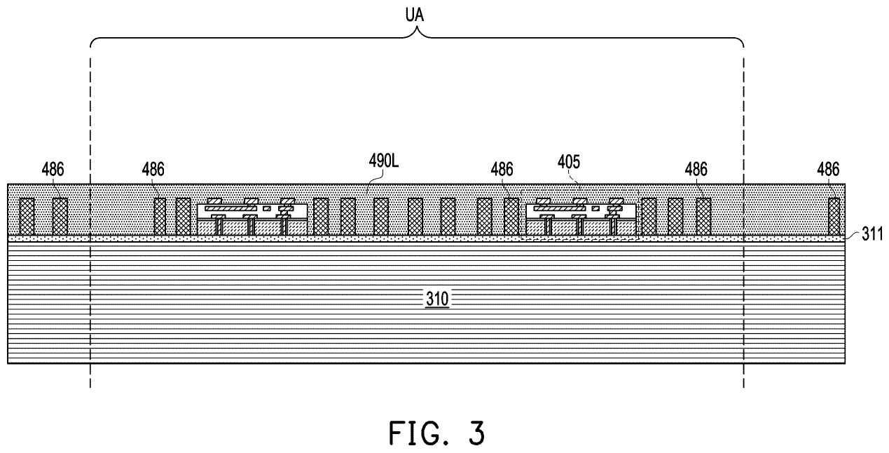

Referring to FIG. 3, an encapsulant, such as a molding compound (MC) may be applied to the gaps within the assembly of the LSI bridges 405 and the TIV structures 486. The MC includes an epoxy-containing compound that may be hardened (i.e., cured) to provide a dielectric material portion having sufficient stiffness and mechanical strength. The MC may include epoxy resin, hardener, silica (as a filler material), and other additives. The MC may be provided in a liquid form or in a solid form depending on the viscosity and flowability. Liquid MC typically provides better handling, good flowability, less voids, better fill, and less flow marks. Solid MC typically provides less cure shrinkage, better stand-off, and less die drift. A high filler content (such as 85% in weight) within an MC may shorten the time in mold, lower the mold shrinkage, and reduce the mold warpage. Uniform filler size distribution in the MC may reduce flow marks, and may enhance flowability.

The MC may be cured at a curing temperature to form an MC matrix, which is herein referred to as a first molding compound (MC) material layer or an interposer-level molding compound (MC) material layer 490L. The interposer-level MC material layer 490L laterally encloses each of the LSI bridges 405 and the TIV structures 486. The interposer-level MC material layer 490L may be a continuous material layer that extends across the entirety of the area of a reconstituted wafer overlying the first carrier wafer 310.

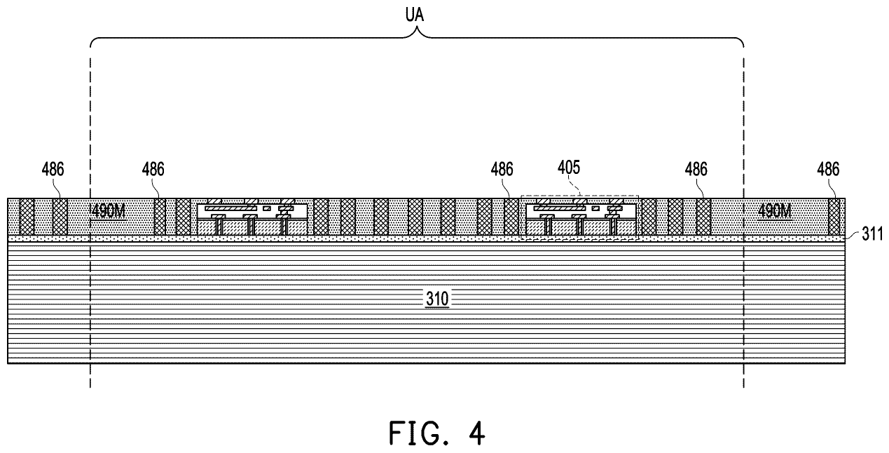

Referring to FIG. 4, excess portions of the interposer-level MC material layer 490L are removed from above the horizontal plane including the top surfaces of the LSI bridge 405 and the TIV structures 486 by a planarization process, which may use chemical mechanical planarization or chemical mechanical polishing (CMP). Surfaces of the through-silicon via structures 414 may be physically exposed after the planarization process. The remaining portion of the interposer-level MC material layer 490L is herein referred to as an interposer-level molding compound (MC) matrix 490M.

The interposer-level MC matrix 490M includes a plurality of molding compound (MC) interposer frames located within a respective unit area UA and are laterally adjoined to one another. Each MC interposer frame corresponds to a portion of the interposer-level MC matrix 490M located within a unit area UA, i.e., an area of a single interposer to be subsequently formed. Each MC interposer frame laterally surrounds a respective set of at least one LSI bridge 405 and a respective array of TIV structures 486.

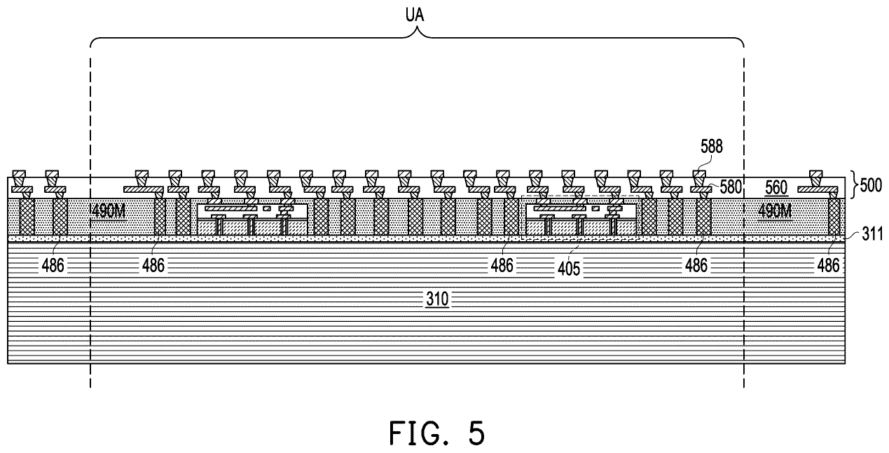

Referring to FIG. 5, a first redistribution structure 500 may be formed on a top side of the two-dimensional repetition of the unit via assembly and the interposer-level MC matrix 490M. The first redistribution structure 500 comprises first redistribution wiring interconnects 580, first redistribution dielectric layers 560, and first bonding structures 588.

The first redistribution dielectric layers 560 include a respective dielectric polymer material such as polyimide (PI), benzocyclobutene (BCB), or polybenzobisoxazole (PBO). Each first redistribution dielectric layer 560 may be formed by spin coating and drying of the respective dielectric polymer material. The thickness of each first redistribution dielectric layer 560 may be in a range from 2 microns to 40 microns, such as from 4 microns to 20 microns. Each first redistribution dielectric layer 560 may be patterned, for example, by applying and patterning a respective photoresist layer thereabove, and by transferring the pattern in the photoresist layer into the first redistribution dielectric layer 560 using an etch process such as an anisotropic etch process. The photoresist layer may be subsequently removed, for example, by ashing.

Each of the first redistribution wiring interconnects 580 may be formed by depositing a metallic seed layer by sputtering, by applying and patterning a photoresist layer over the metallic seed layer to form a pattern of openings through the photoresist layer, by electroplating a metallic fill material (such as copper, nickel, or a stack of copper and nickel), by removing the photoresist layer (for example, by ashing), and by etching portions of the metallic seed layer located between the electroplated metallic fill material portions. The metallic seed layer may include, for example, a stack of a titanium barrier layer and a copper seed layer. The titanium barrier layer may have thickness in a range from 50 nm to 300 nm, and the copper seed layer may have a thickness in a range from 100 nm to 500 nm. The metallic fill material for the first redistribution wiring interconnects 580 may include copper, nickel, or copper and nickel. The thickness of the metallic fill material that is deposited for each first redistribution wiring interconnect 580 may be in a range from 2 microns to 40 microns, such as from 4 microns to 10 microns, although lesser or greater thicknesses may also be used. The total number of levels of wiring in the first redistribution structure 500 (i.e., the levels of the first redistribution wiring interconnects 580) may be in a range from 1 to 10.

The first bonding structures 588 may comprise microbump structures that may be subsequently used to attach semiconductor dies. The metallic fill material for the microbump structures may include copper. The first bonding structures 588 may have horizontal cross-sectional shapes of rectangles, rounded rectangles, or circles. Other horizontal cross-sectional shapes may be within the contemplated scope of disclosure. Typically, the first bonding structures 588 may be configured for microbump bonding, and may have a thickness in a range from 5 microns to 100 microns, although lesser or greater thicknesses may also be used. In one embodiment, the first bonding structures 588 within each unit area UA may be formed as at least one array of microbumps (such as copper pillars). Each of the microbumps may have a lateral dimension in a range from 10 microns to 50 microns, and may have a pitch in a range from 20 microns to 100 microns.

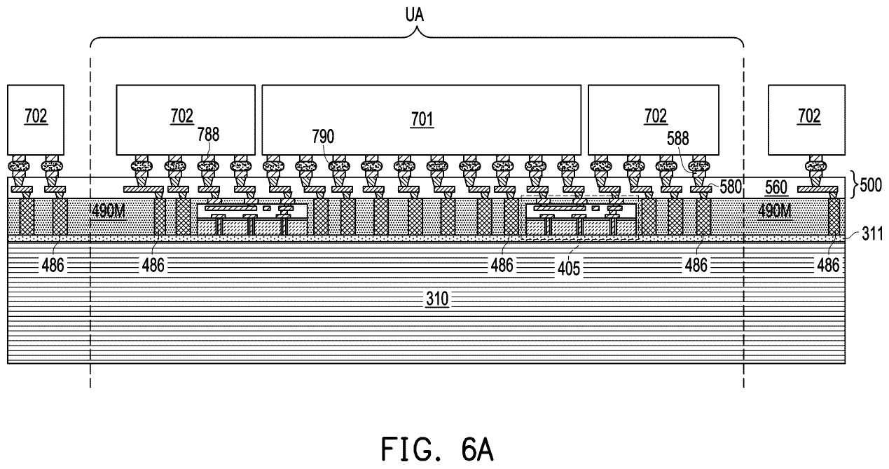

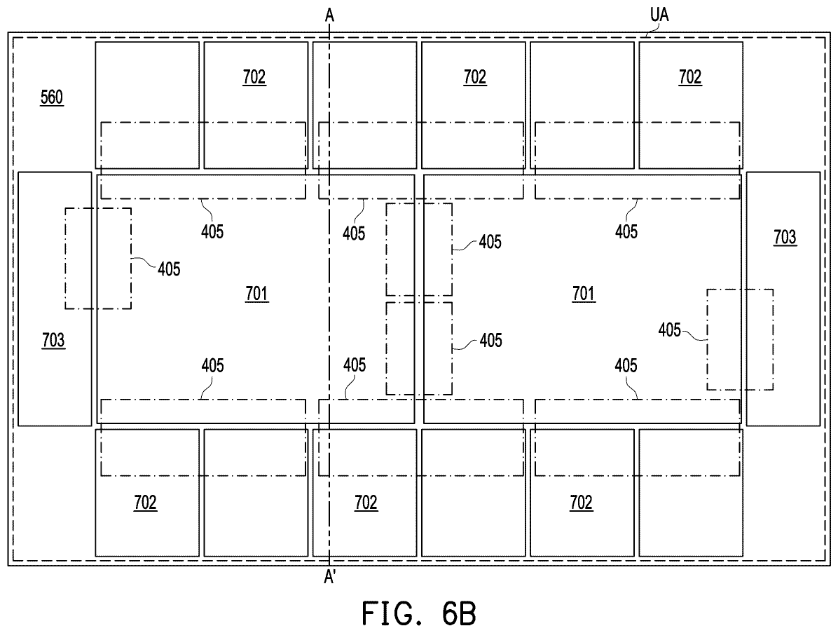

Referring to FIGS. 6A and 6B, a set of at least one semiconductor die (701, 702, 703) may be bonded to a respective set of first bonding structures 588 within each unit area UA. Each set of at least one semiconductor die (701, 702, 703) includes at least one semiconductor die, and may comprise a plurality of semiconductor dies (701, 702, 703). For example, each set of at least one semiconductor die (701, 702, 703) may include at least one system-on-chip (SoC) die 701, at least one memory die 702, and/or at least one input/output (I/O) die 703. Each SoC die 701 may comprise an application processor die, a central processing unit die, or a graphic processing unit die. In one embodiment, the at least one memory die 702 may comprise a high bandwidth memory (HBM) die that includes a vertical stack of static random access memory dies. In one embodiment, the at least one input/output die 703 may comprise input/output circuits for interfacing with external inputs and outputs for the SoC die(s) 701 and/or the memory die(s) 702. In one embodiment, the at least one semiconductor die (701, 702, 703) may include at least one system-on-chip (SoC) die 701 and at least one high bandwidth memory (HBM) die. Each HBM die may comprise a vertical stack of static random access memory (SRAM) dies that are interconnected to one another through arrays of microbumps and are laterally surrounded by a respective molding material enclosure frame.

Each semiconductor die (701, 702, 703) may comprise a respective array of on-die bump structures 788. Solder material portions may be applied to the on-die bump structures 788 of the semiconductor dies (701, 702, 703), or may be applied to the first bonding structures 588. The solder material portions are herein referred to as die-interposer-bonding (DIB) solder material portions 790, or as first solder material portions. Each of the semiconductor dies (701, 702, 703) may be positioned in a face-down position such that on-die bump structures 788 face the first bonding structures 588. Placement of the semiconductor dies (701, 702, 703) may be performed using a pick and place apparatus such that each of the on-die bump structures 788 may face a respective one of the first bonding structures 588. Each set of at least one semiconductor die (701, 702, 703) may be placed within a respective unit area. A DIB solder material portion 790 is attached to one of the on-die bump structure 788 and the first bonding structure 588 for each facing pair of an on-die bump structure 788 and a first bonding structure 588.

In one embodiment, the on-die bump structures 788 and the first bonding structures 588 may be configured for microbump bonding. In this embodiment, each of the on-die bump structures 788 and the first bonding structures 588 may be configured as copper pillar structures having a diameter in a range from 10 microns to 50 microns, and may have a respective height in a range from 5 microns to 100 microns. The pitch of the microbumps in the direction of periodicity may be in a range from 20 microns to 100 microns, although lesser and greater pitches may also be used. Upon reflow, the lateral dimensions of each DIB solder material portion 790 may be in a range from 100% to 150% of the lateral dimension (such as a diameter) of the adjoined on-die bump structure 788 or of the adjoined first bonding structure 588.

The LSI bridges 405 may provide electrical interconnection between neighboring pairs of semiconductor dies (701, 702, 703). Generally, a LSI bridge 405 may electrically connect an SoC die 701 and a memory die 702, a neighboring pair of SoC dies 701, or an SoC die 701 and an input/output die 703.

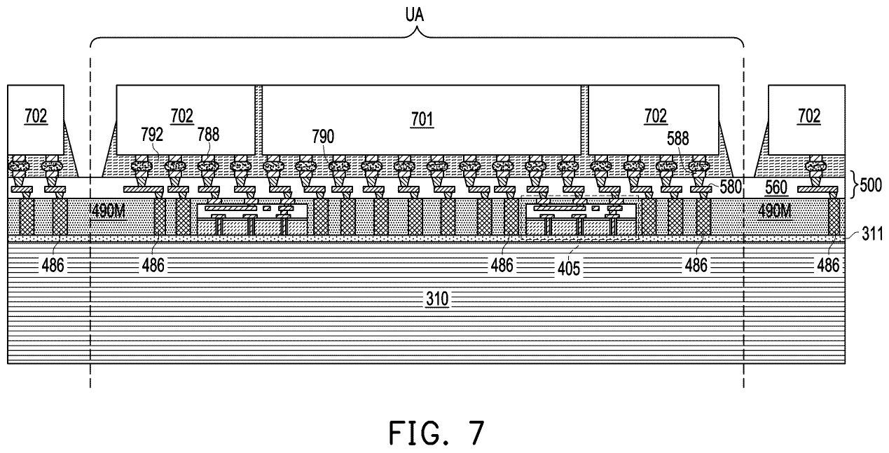

Referring to FIG. 7, a die-side underfill material may be applied into each gap between the first redistribution structure 500 and a respective set of at least one semiconductor die (701, 702, 703). The die-side underfill material may comprise any underfill material known in the art. A die-side underfill material portion 792 may be formed within each unit area UA between the first redistribution structure 500 and the respective set of at least one semiconductor die (701, 702, 703). The die-side underfill material portions 792 may be formed by injecting the die-side underfill material around a respective array of DIB solder material portions 790 in a respective unit area UA. Any known underfill material application method may be used, which may be, for example, the capillary underfill method, the molded underfill method, or the printed underfill method.

A die-side underfill material portion 792 may laterally surround, and contact, a respective set of the DIB solder material portions 790 within the unit area UA. The die-side underfill material portion 792 may be formed around, and contact, the DIB solder material portions 790, the first bonding structures 588, and the on-die bump structures 788 in the unit area. Generally, at least one semiconductor die (701, 702, 703) comprising a respective set of on-die bump structures 788 is attached to the first redistribution structure 500 through a respective set of DIB solder material portions 790 within each unit area UA.

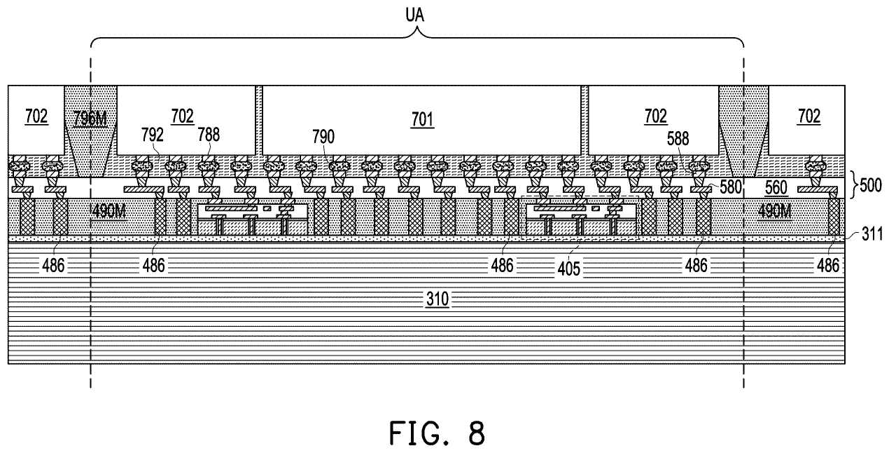

Referring to FIG. 8, a molding compound (MC) may be applied to the gaps between assemblies of a respective set of semiconductor dies (701, 702, 703) and a respective die-side underfill material portion 792. The MC may include any material that may be used for the interposer-level MC matrix 490M discussed above. The MC may include epoxy resin, hardener, silica (as a filler material), and other additives. The MC may be cured at a curing temperature to form an MC matrix, which is herein referred to as a die-level MC matrix 796M or as a second MC matrix. The die-level MC matrix 796M laterally surrounds and embeds each assembly of a set of semiconductor dies (701, 702, 703) and a die-side underfill material portion 792. The die-level MC matrix 796M includes a plurality of molding compound (MC) die frames that are laterally adjoined to one another. Each MC die frame is a portion of the die-level MC matrix 796M that is located within a respective unit area UA. Thus, each MC die frame laterally surrounds, and embeds, a respective a set of semiconductor dies (701, 702, 703) and a respective die-side underfill material portion 792. Young's modulus of pure epoxy is about 3.35 GPa, and Young's modulus of the MC may be higher than Young's modulus of pure epoxy due to additives therein. Thus, Young's modulus of the die-level MC matrix 796M may be greater than 3.5 GPa.

Portions of the die-level MC matrix 796M that overlies the horizontal plane including the top surfaces of the semiconductor dies (701, 702, 703) may be removed by a planarization process. For example, the portions of the die-level MC matrix 796M that overlies the horizontal plane may be removed using a chemical mechanical planarization (CMP). The reconstituted wafer that overlies the first carrier wafer 310 comprises a combination of the die-level MC matrix 796M, the semiconductor dies (701, 702, 703), the die-side underfill material portions 792, the first redistribution structure 500, a two-dimensional array of combinations of at least one LSI bridge 405, and the TIV structures 486. Each portion of the die-level MC matrix 796M located within a unit area UA constitutes an MC die frame.

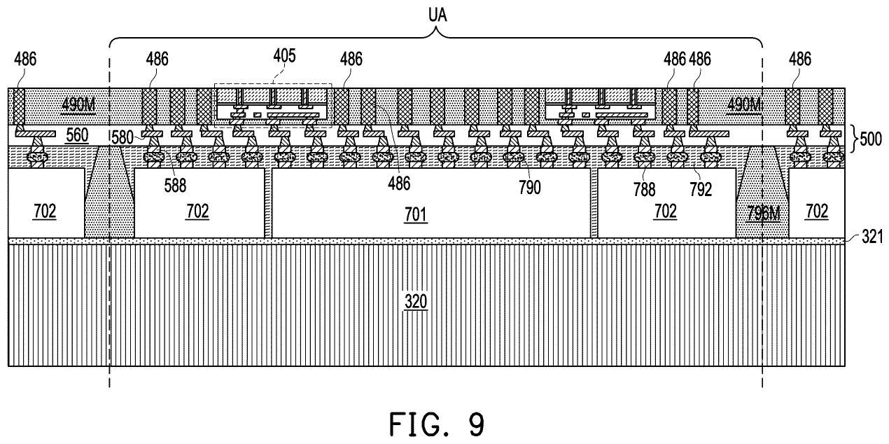

Referring to FIG. 9, a second adhesive layer 321 may be applied over the die-level MC matrix 796M. The second adhesive layer 321 may comprise a light-to-heat conversion (LTHC) layer or a thermally decomposing adhesive material layer depending on the removal mechanism to be subsequently used. A second carrier wafer 320 may be attached to the die-level MC matrix 796M and the semiconductor dies (701, 702, 703) through the second adhesive layer 321. The second carrier wafer 320 may comprise any material that may be used for the first carrier wafer 310, and generally may have about the same thickness range as the first carrier wafer 310.

The first carrier wafer 310 may be detached from the reconstituted wafer. In some embodiments, the first carrier wafer 310 and the first adhesive layer 311 may be removed by backside grinding. Optionally, at least one selective etch process (such as a wet etch process or a reactive ion etch process) may be used in conjunction with the backside grinding process to minimize collateral removal of surface portions of the LSI bridges 405, and the TIV structures 486. Alternatively or additionally, in embodiments in which the first carrier wafer 310 includes an optically transparent material and the first adhesive layer 311 comprises a light-to-heat conversion material, irradiation through the first carrier wafer 310 may be used to detach the first carrier wafer 310. In embodiments in which the first adhesive layer 311 comprises a thermally decomposable adhesive material, an anneal process or a laser irradiation may be used to detach the first carrier wafer 310. A suitable clean process may be performed to remove residual portions of the first adhesive layer 311.

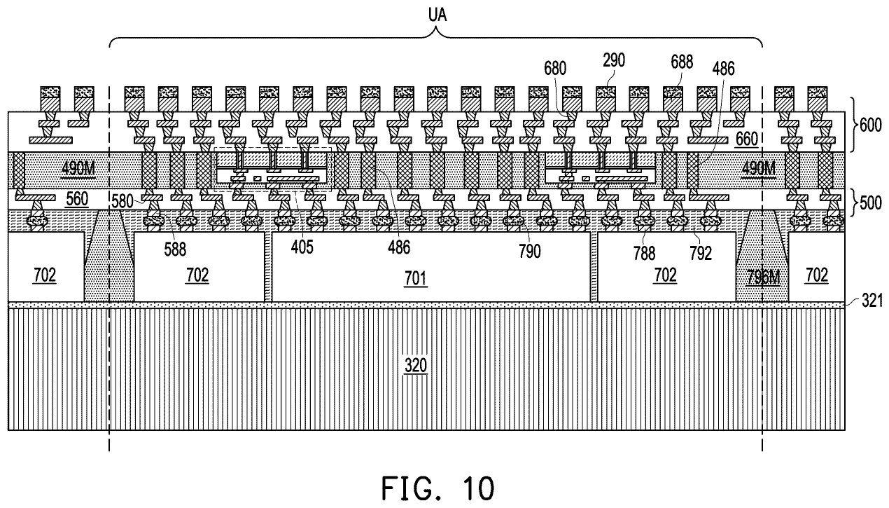

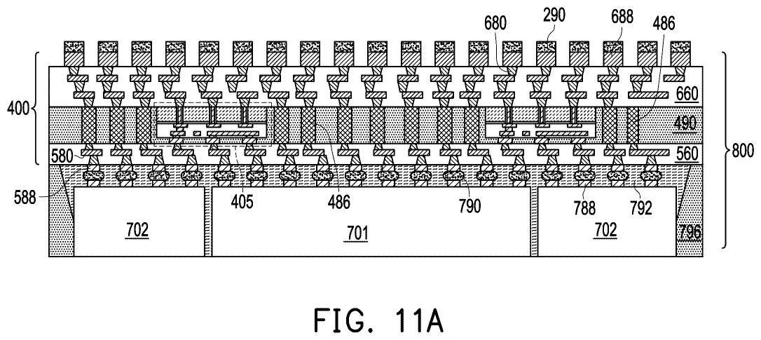

Referring to FIG. 10, a second redistribution structure 600 may be formed on a physically exposed side of the two-dimensional repetition of the unit via assembly and the interposer-level MC matrix 490M. The second redistribution structure 600 comprises second redistribution wiring interconnects 680, optional second interconnect-level alignment structures (not shown), second redistribution dielectric layers 660, and second bonding structures 688. Generally, the second redistribution structure 600 may be formed in the same manner as the first redistribution structures 500 with suitable changes in the lithographic pattern and/or in the thicknesses and material compositions of material layers. The second bonding structures 688 may be formed as bonding pads that are configured for controlled collapse chip connection (C4) bonding.

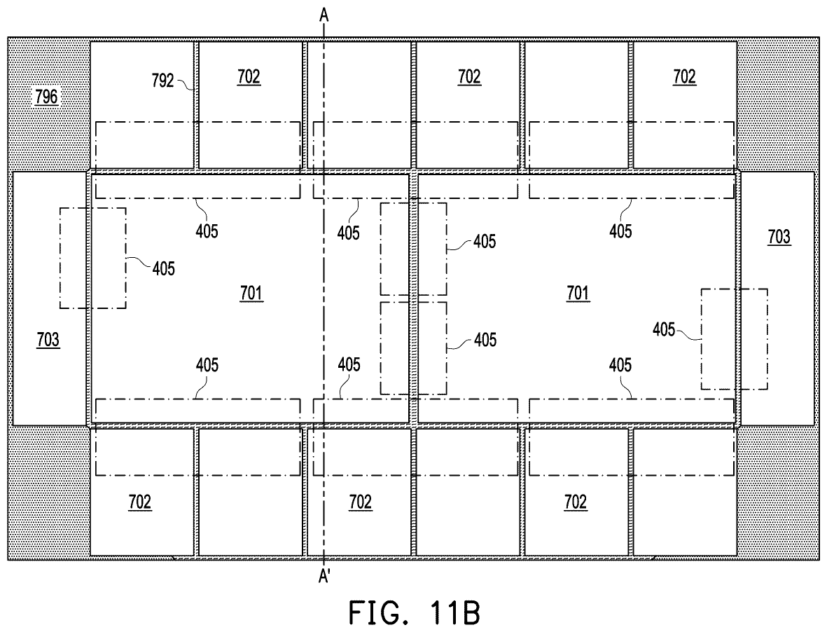

Referring to FIGS. 11A and 11B, the second carrier wafer 320 may be detached from the reconstituted wafer. In embodiments in which the second carrier wafer 320 includes an optically transparent material and the second adhesive layer 321 comprises a light-to-heat conversion material, irradiation through the second carrier wafer 320 may be used to detach the second carrier wafer 320. In embodiments in which the second adhesive layer 321 comprises a thermally decomposable adhesive material, an anneal process or a laser irradiation may be used to detach the second carrier wafer 320. A suitable clean process may be performed to remove residual portions of the second adhesive layer 321. A horizontal surface of the die-level MC matrix 796M may be physically exposed.

The reconstituted wafer includes a two-dimensional array of interposer dies 400, and further includes a two-dimensional array of sets of at least one semiconductor die (701, 702, 703) that are bonded to a respective interposer die 400. The reconstituted wafer may be diced along dicing channels (which correspond to the dicing lines DL described above) by performing a dicing process. The dicing channels correspond to the boundaries between neighboring pairs of unit areas UA. Each diced unit from the reconstituted wafer comprises a composite package 800. Each diced portion of the die-level MC matrix 796M constitutes a die-level molding compound (MC) frame 796, which is also referred to as a die frame 796. Each diced portion of the interposer-level MC matrix 490M constitutes an interposer-level MC frame 490.

The diced portions of the reconstituted wafer comprise composite packages 800, which may be fan-out packages. Each composite package 800 comprises at least one semiconductor die (701, 702, 703), an interposer die 400, a die-side underfill material portion 792, a die frame 796, and at least one array of DIB solder material portions 790. Each interposer die 400 comprises a unit via assembly including TIV structures 486, at least one LSI bridge 405, an interposer-level MC frame 490, a first redistribution structure 500, and a second redistribution structure 600.

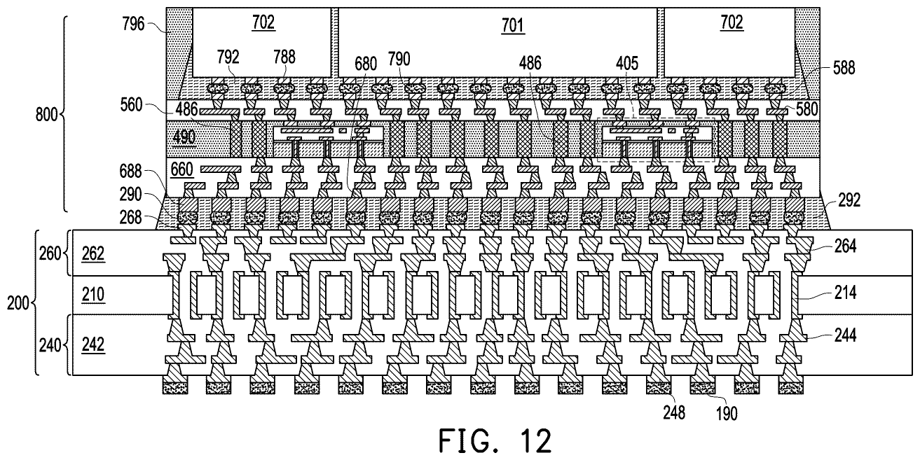

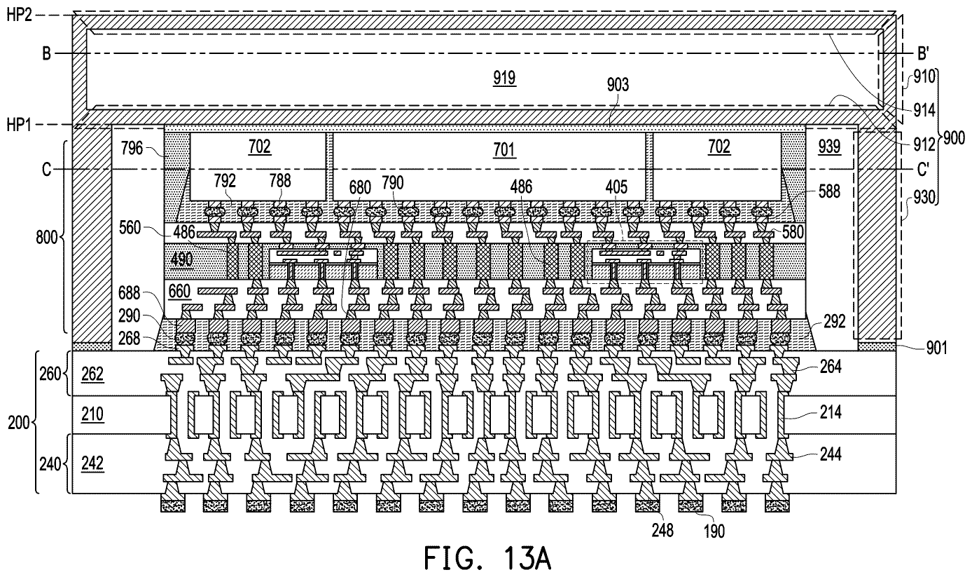

Referring to FIG. 12, a packaging substrate 200 may be bonded to the composite package 800. The packaging substrate 200 may be a cored packaging substrate including a core substrate 210, or a coreless packaging substrate that does not include a package core. Alternatively, the packaging substrate 200 may include a system-on-integrated packaging substrate (SoIS) including redistribution layers. dielectric interlayers, and/or at least one embedded interposer (such as a silicon interposer). Such a system-integrated packaging substrate may include layer-to-layer interconnections using solder material portions, microbumps, underfill material portions (such as molded underfill material portions), and/or an adhesion film. While the present disclosure is described using a cored packaging substrate, the scope of the present disclosure is not limited by any particular type of substrate package. For example, an SoIS may be used in lieu of a cored packaging substrate. In embodiments in which SoIS is used, the core substrate 210 may include a glass epoxy plate including an array of through-plate holes. An array of through-core via structures 214 including a metallic material may be provided in the through-plate holes. Each through-core via structure 214 may, or may not, include a cylindrical hollow therein. Optionally, dielectric liners (not illustrated) may be used to electrically isolate the through-core via structures 214 from the core substrate 210.

The packaging substrate 200 may include board-side surface laminar circuit (SLC) 240 and a chip-side surface laminar circuit (SLC) 260. The board-side SLC may include board-side insulating layers 242 embedding board-side wiring interconnects 244. The chip-side SLC 260 may include chip-side insulating layers 262 embedding chip-side wiring interconnects 264. The board-side insulating layers 242 and the chip-side insulating layers 262 may include a photosensitive epoxy material that may be lithographically patterned and subsequently cured. The board-side wiring interconnects 244 and the chip-side wiring interconnects 264 may include copper that may be deposited by electroplating within patterns in the board-side insulating layers 242 or the chip-side insulating layers 262.

In one embodiment, the chip-side surface laminar circuit 260 comprises chip-side wiring interconnects 264 that are connected to an array of substrate bonding pads 268. The array of substrate bonding pads 268 may be configured to allow bonding through C4 solder balls. The board-side surface laminar circuit 240 comprises board-side wiring interconnects 244 that are connected to an array of board-side bonding pads 248. The array of board-side bonding pads 248 is configured to allow bonding through solder material portions having a greater dimension than the C4 solder balls. While the present disclosure is described using an embodiment in which the packaging substrate 200 includes a chip-side surface laminar circuit 260 and a board-side surface laminar circuit 240, embodiments are expressly contemplated herein in which one of the chip-side surface laminar circuit 260 and the board-side surface laminar circuit 240 is omitted, or is replaced with an array of bonding structures such as microbumps. In an illustrative example, the chip-side surface laminar circuit 260 may be replaced with an array of microbumps or any other array of bonding structures.

The composite package 800 may be attached to the packaging substrate 200 using the second solder material portions, which are herein referred to interposer-substrate-bonding (ISB) solder material portions 290. Specifically, each of the ISB solder material portions 290 may be bonded to a respective one of the substrate bonding pads 268 and to a respective one of the second bonding structures 688 located on the composite package 800. A reflow process may be performed to reflow the ISB solder material portions 290 such that each ISB solder material portion 290 may be bonded to a respective one of the substrate bonding pads 268 and to a respective one of the second bonding structures 688.

An underfill material may be applied into a gap between the composite package 800 and the packaging substrate 200. The underfill material may comprise any underfill material known in the art. An underfill material portion may be formed around the ISB solder material portions 290 in the gap between the composite package 800 and the packaging substrate 200. This underfill material portion is herein referred to as an interposer-substrate underfill material portion 292, or as an IP underfill material portion 292. An array of solder material portions 190 may be formed on the array of board-side bonding pads 248. A bonded assembly (800, 200) including a composite package 800 and a packaging substrate 200 may be formed.

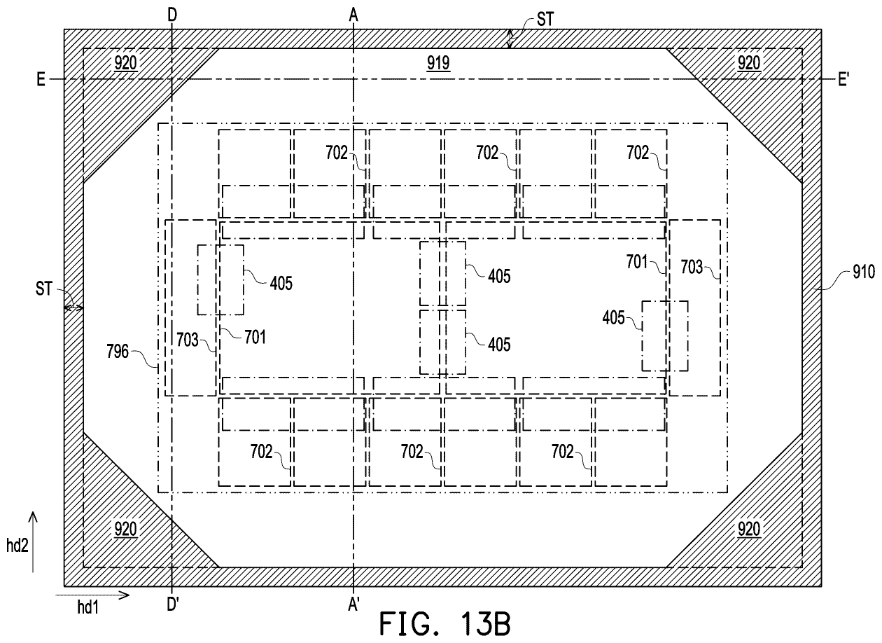

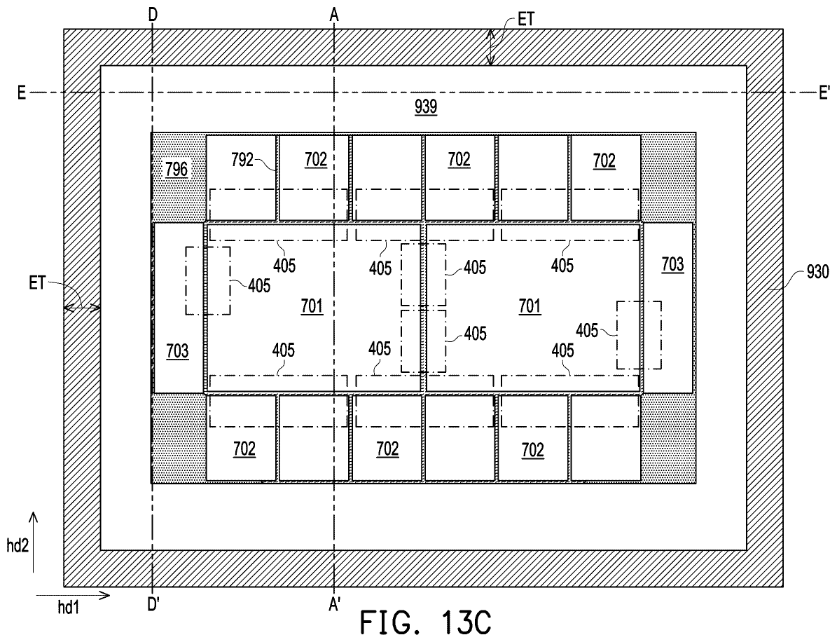

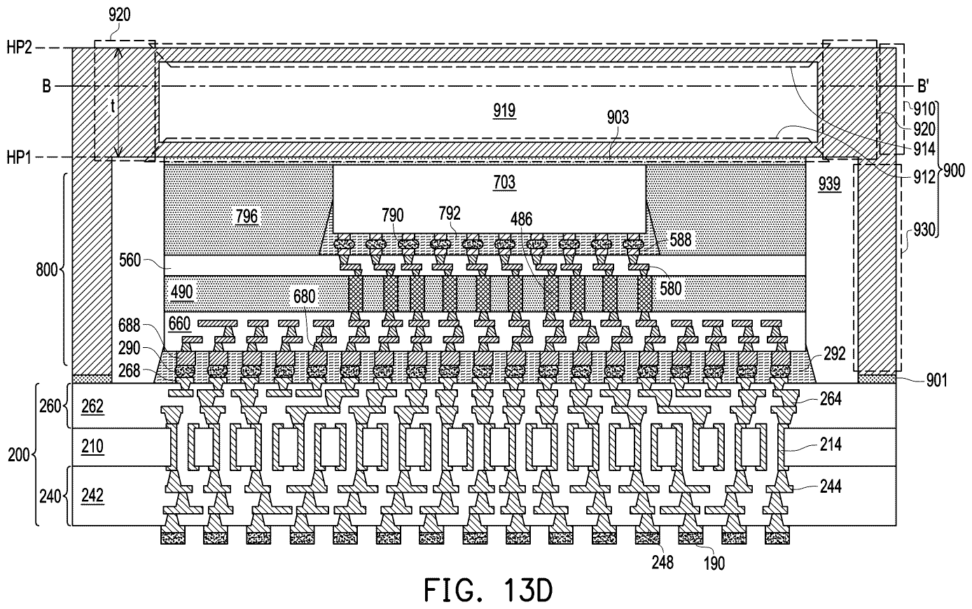

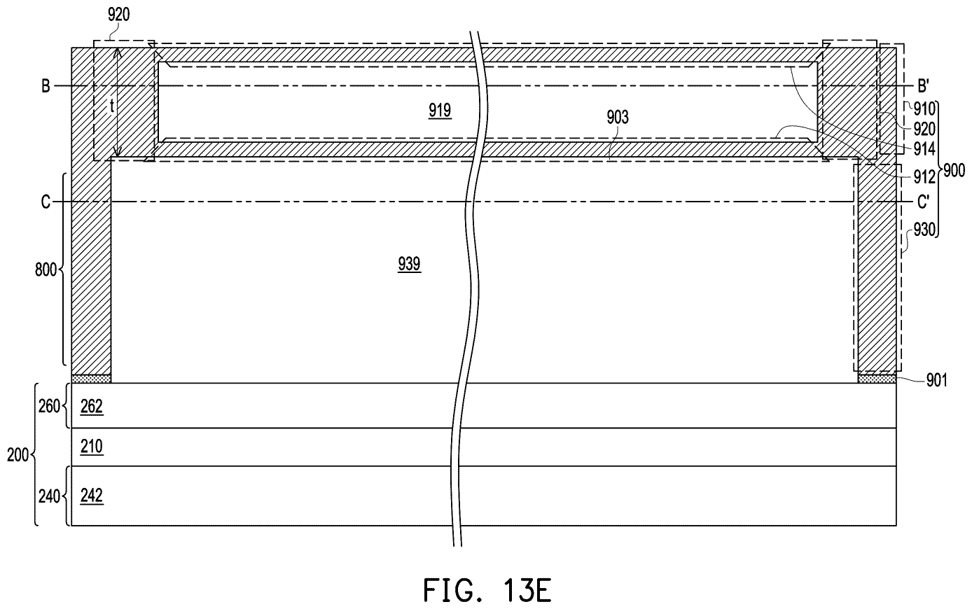

Referring to FIGS. 13A and 13B, a lid structure 900 configured to be attached to the bonded assembly (800, 200) is provided. The lid structure 900 comprises a thermally conductive material, which may comprise a metallic material (such as copper, aluminum, or a metallic alloy), a thermally conductive ceramic material (such as aluminum nitride, aluminum oxide, or silicon carbide), or graphite. The lid structure 900 comprises a cavity 919, which is also referred to a vapor chamber, within a region that overlaps with the at least one semiconductor die (701, 702, 703) upon mounting to the bonded assembly (800, 200). Further, the lid structure 900 comprises an enclosure wall portion 930 that laterally surrounds the composite package 800 upon mounting to the bonded assembly (800, 200). According to an aspect of the present disclosure, the shape of the cavity 919 within the lid structure 900 is selected such that the area of the cavity 919 in a plan view (such as a see-through top-down view) overlaps with the entire area of the at least one semiconductor die (701, 702, 703) in the bonded assembly (800, 200) upon mounting of the lid structure 900 to the bonded assembly (800, 200). A plan view refers to a view along a vertical direction in which the silhouette of each structural element is delineated in a projection onto a horizontal plane irrespective of whether the structural elements are visible or invisible from the outside. For example, the inner sidewalls of the lid structure 900 that define the lateral extents of the cavity 919 are visible in the plan view although the inner sidewalls of the lid structure 900 are not visible from the outside.

According to an aspect of the present disclosure, the lid structure 900 comprises a bottom plate portion 912 having a first uniform vertical thickness, a top plate portion 914 that is vertically spaced from the bottom plate portion 912 and having a second uniform vertical thickness, a sidewall frame portion 910 laterally surrounding a cavity 919 located between the bottom plate portion 912 and the top plate portion 914 and having a uniform sidewall thickness ST, and solid block portions 920 located within the sidewall frame portion 910 and vertically extending from a first horizontal plane HP1 including a bottom surface of the bottom plate portion 912 to a second horizontal plane HP2 including a top surface of the top plate portion 914 and located in corner regions of the lid structure 900. The first uniform vertical thickness may be in a range from 0.5 mm to 3 mm, and the second uniform vertical thickness may be in a range from 0.5 mm to 3 mm.

The vertical distance between the bottom plate portion 912 and the top plate portion 914 may be in a range from 1 mm to 5 mm, although lesser or greater vertical distances may also be used. The uniform sidewall thickness ST may be in a range from 0.5 mm to 5 mm, although lesser and greater thicknesses may also be used. For the purpose of the present disclosure, the entire portion of the lid structure 900 that overlies the first horizontal plane HP1 and is laterally spaced from the outer vertical sidewalls of the lid structure 900 by a lateral distance that is not greater than the uniform sidewall thickness ST is considered to be the sidewall frame portion 910. The vertical thickness t of each solid block portion 920 may be the same as the vertical separation distance between the first horizontal plane HP1 and the second horizontal plane HP2. Each solid block portion 920 may be free of any void therein.

In one embodiment, the lid structure 900 comprises an enclosure wall portion 930 extending downward from a peripheral region of the bottom plate portion 912. The outer sidewalls of the enclosure wall portion 930 may be vertically coincident with outer sidewalls of the sidewall frame portion 910, i.e., may be located within a same set of vertical planes. The enclosure wall portion 930 may comprise a set of four adjoined vertically-extending walls that laterally encloses a void. Each wall of the enclosure wall portion 930 may have a uniform width, which is herein referred to as an enclosure wall thickness ET. The enclosure wall thickness ET may be in a range from 0.5 mm to 5 mm, although lesser or greater thicknesses may also be used.

A horizontal cross-sectional shape of the sidewall frame portion 910 may comprise a pair of first outer sidewalls laterally extending along a first horizontal direction hd1 and a pair of second outer sidewalls laterally extending along a second horizontal direction hd2 that is perpendicular to the first horizontal direction hd1. In one embodiment, the enclosure wall portion 930 may comprise two first outer sidewalls that are parallel to the first horizontal direction hd1 and two second outer sidewalls that are parallel to the second horizontal direction hd2. In one embodiment, the first outer sidewalls of the enclosure wall portion 930 may be vertically coincident with the first outer sidewalls of the sidewall frame portion 910, and the second outer sidewalls of the enclosure wall portion 930 may be vertically coincident with the second outer sidewalls of the sidewall frame portion 910.

A thermal interface material may be applied on the top surface of the composite package 800, which include the top surfaces of the at least one semiconductor die (701, 702, 703) and the die frame 796. Alternatively or additionally, a thermal interface material may be applied to the bottom surface of the bottom plate portion 912 of the lid structure 900. The thermal interface material that is applied to the top surface(s) of the at least one semiconductor die (701, 702, 703) and/or to the bottom surface of the bottom plate portion 912 may be any thermal interface material known in the art. For example, the thermal interface material may comprise thermal grease, thermal pads, phase-change materials, liquid metals, or thermally conductive adhesives. The thickness of the thermal interface material may be in a range from 10 microns to 500 microns, although lesser or greater thicknesses may also be used. While application of the thermal interface material with a uniform thickness is desirable, variability in the thickness and/or coverage of the thermal interface material on the surfaces of the composite package or the bottom surface of the bottom plate portion 912 may be introduced during application. Further, local thickness variations may be induced in the applied portion of the thermal interface material during subsequent bonding between the composite package 800 and the lid structure 900 and during conversion of the applied portion of the thermal interface material into a thermal interface material layer 903. According to an aspect of the present disclosure, the lid structure 900 is configured to be conducive to testing and inspection of the thermal interface material layer 903 after the lid structure 900 is attached to the bonded assembly (800, 200) of the composite package 800 and the packaging substrate 200.

The lid structure 900 may be attached to the bonded assembly (800, 200) comprising at least one semiconductor die (701, 702, 703) using an adhesive layer 901. In one embodiment, the adhesive layer 901 bonds the lid structure 900 to the packaging substrate 200. In one embodiment, the adhesive layer 901 may be applied to a first element selected from the packaging substrate 200 and the lid structure 900, and a second element selected from the packaging substrate 200 and the lid structure 900 and different from the first element may be brought into contact with the adhesive layer 901. In an illustrative example, the adhesive layer 901 may be applied to a peripheral portion of the top surface of the packaging substrate 200. In the illustrated example, the adhesive layer 901 is applied between the packaging substrate 200 and a frame-shaped bottom surface of the enclosure wall portion 930 of the lid structure 900. In this embodiment, the enclosure wall portion 930 may be attached to a frame-shaped surface segment of a top surface of the packaging substrate 200 through the adhesive layer 901, and laterally surrounds the composite package 800.

The thermal interface material that is applied to the top surface(s) of the at least one semiconductor die (701, 702, 703) and/or to the bottom surface of the bottom plate portion 912 of the lid structure 900 is converted into a thermal interface material (TIM) layer 903 generally having a uniform thickness. Thus, the lid structure 900 is attached to the bonded assembly (800, 200) such that TIM layer 903 is interposed between the at least one semiconductor die (701, 702, 703) and the bottom plate portion 912. Generally, the TIM layer 903 is formed by application of a thermal interface material to each top surface of the at least one semiconductor die (701, 702, 703) or to a bottom surface of the bottom plate portion 912, and by pressing the thermal interface material between the at least one semiconductor die (701, 702, 703) and the lid structure 900. According to an aspect of the present disclosure, the solid block portions 920 of the lid structure 900 are configured to be located entirely outside areas of, i.e., not to have any areal overlap with, the at least one semiconductor die (701, 702, 703) in a plan view along a vertical direction upon attachment of the lid structure 900 to the packaging substrate 200.

Generally, the TIM layer 903 has a uniform thickness throughout unless misprocessing occurs during bonding of the lid structure 900 to the packaging substrate 200. Further, the TIM layer 903 does not have a bald spot (i.e., a spot in which the thermal interface material is missing) therein unless misprocessing occurs during bonding of the lid structure 900 to the packaging substrate 200. While the general configurations of the components of the lid structure 900, the TIM layer 903, and the at least one semiconductor die (701, 702, 703) are described below for normally processed structures on which misprocessing does not occur, misprocessing may occur during manufacturing processes, and an advantage of embodiments of the present disclosure is the ability to detect packaging structures that contain defective components or defective configurations due to such misprocessing, for example, through subsequent X-ray inspection. Thus, it should be understood that the geometries described below generally apply to packaging structures that pass subsequent X-ray inspection. For example, while the TIM layer 903 has a uniform thickness for normally processed packaging structures, non-uniform thickness for the TIM layer 903 may be a reason for screening out a defective packaging structure. Further, while the TIM layer 903 is supposed to cover the entire area of the at least one semiconductor die (701, 702, 703) and most packaging structures pass this criterion, insufficient coverage of the at least one semiconductor die (701, 702, 703) by the TIM layer 903 may be grounds for rendering a packaging structure defective.

Generally, for packaging structures that are processed without defects, the TIM layer 903 has an areal overlap with the entirety of the at least one semiconductor die (701, 702, 703) in the plan view upon attachment of the lid structure 900 to the bonded assembly (800, 200). In one embodiment, the lid structure 900 further comprises an enclosure wall portion 930 extending downward from a peripheral region of the bottom plate portion 912 and attached to a frame-shaped surface segment of the top surface of the packaging substrate 200 through the adhesive layer 901. Upon attachment of the lid structure 900 to the packaging substrate 200, a frame-shaped void 939 may be formed around the composite package 800 between sidewalls of the composite package 800 and inner sidewalls of the enclosure wall portion 930.

In the configuration illustrated in FIG. 13A-13E, the solid block portions 920 are located outside an area of the composite package 800 in the plan view. In one embodiment, the lid structure 900 may be aligned to the bonded assembly (800, 200) during attachment of the lid structure 900 to the bonded assembly (800, 200) such that the solid block portions 920 are located entirely outside areas of, i.e., do not have any areal overlap with, the die frame 796. In one embodiment, the solid block portions 920 may comprise, or may consist of, four solid block portions 920 having a respective triangular horizontal shape and located at four corners of the lid structure 900. In this embodiment, the X-ray beam used during a subsequent X-ray examination is attenuated in the areas of the solid block portions 920 and the sidewall frame portion 910, but is not attenuated in the area of the cavity 919. Thus, examination of the entire portion of the TIM layer 903 during the subsequent X-ray examination is possible.

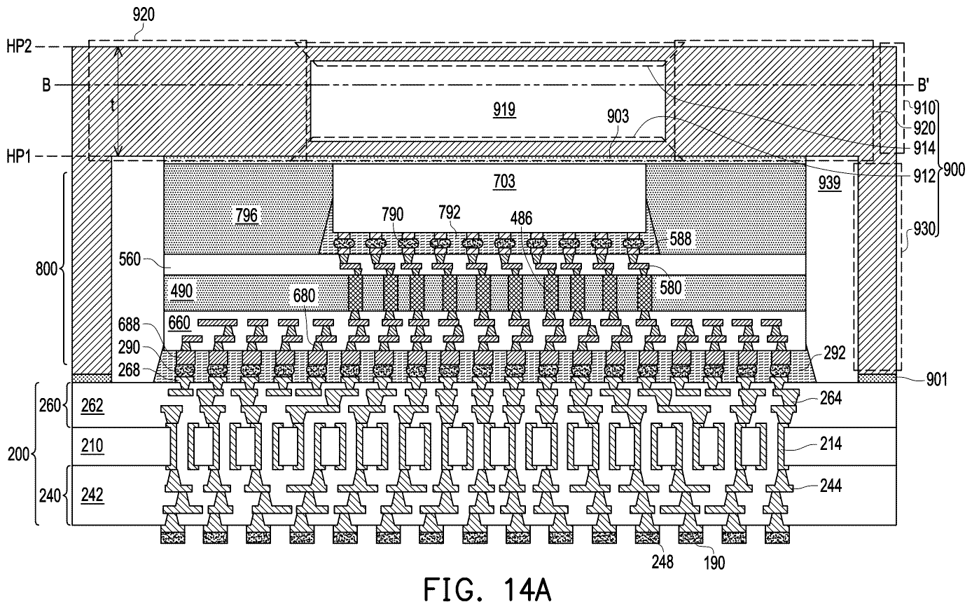

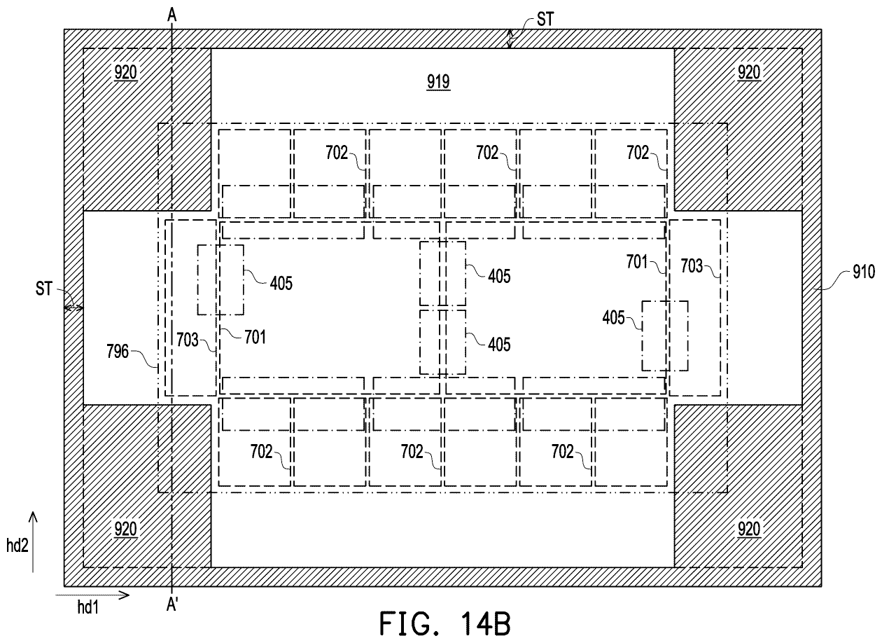

Referring to FIGS. 14A and 14B, a first alternative configuration of the packaging structure is illustrated, which may be derived from the packaging structure illustrated in FIG. 13A-13E by modifying the pattern of the solid block portions 920 and the cavity 919. In the first alternative configuration illustrated in FIGS. 14A and 14B, the solid block portions 920 have an areal overlap with peripheral regions of the composite package 800 in the plan view. In one embodiment, the lid structure 900 may be aligned to the bonded assembly (800, 200) during attachment of the lid structure 900 to the bonded assembly (800, 200) such that the solid block portions 920 have a partial areal overlap with the frame-shaped void 939 and a partial areal overlap with the die frame 796 upon attaching the lid structure 900 to the bonded assembly (800, 200).

In one embodiment, the solid block portions 920 may comprise, or may consist of, four solid block portions 920 having a respective rectangular horizontal shape and located at four corners of the lid structure 900. The solid block portions 920 may comprise areas that overlap with the die frame 796 in the plan view. Specifically, corner regions of the die frame 796 may overlap with the solid block portions 920 in the plan view. In this embodiment, the X-ray beam used during a subsequent X-ray examination is attenuated in the areas of the solid block portions 920 and the sidewall frame portion 910, and thus, corner regions of the die frame 796 are excluded from the examination area during a subsequent X-ray examination.

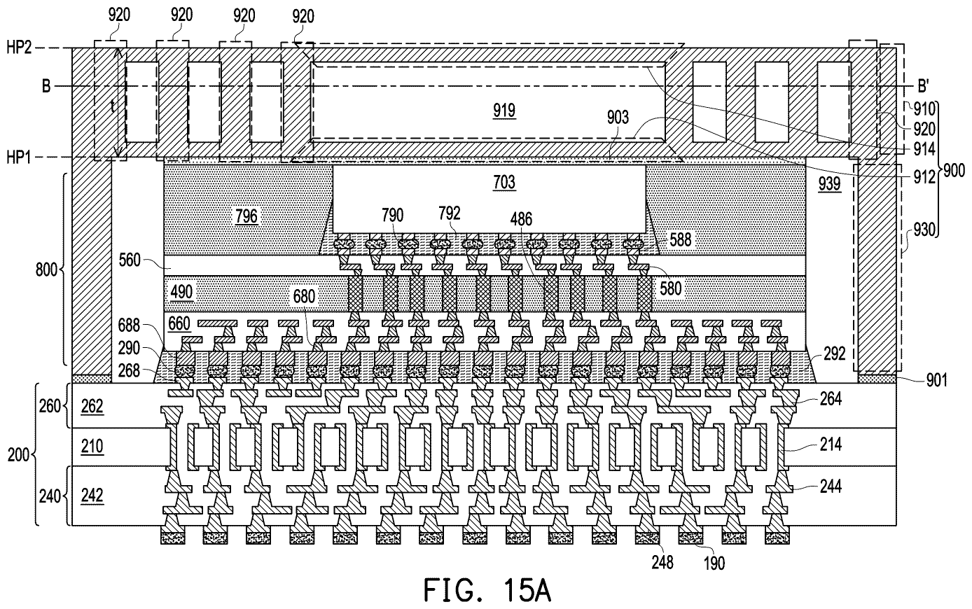

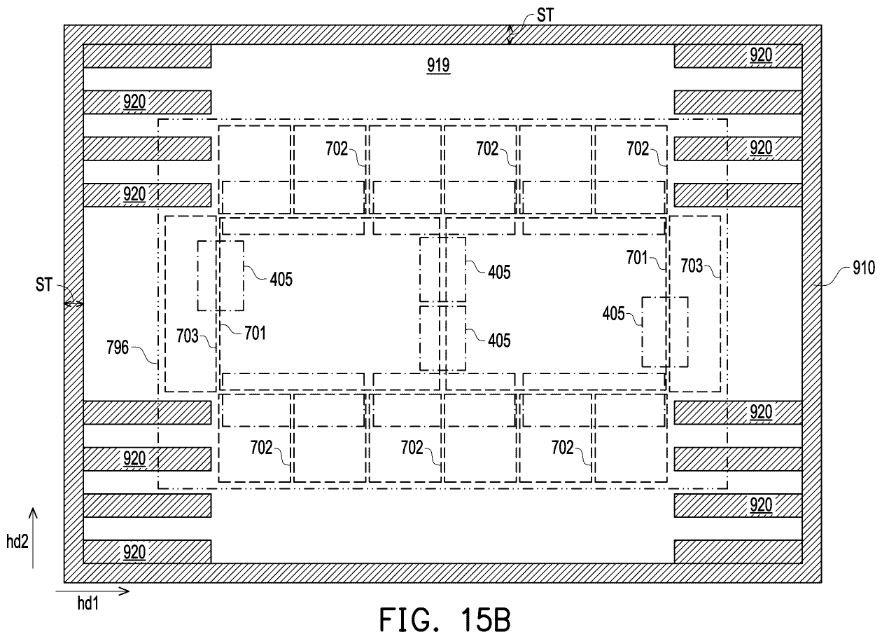

Referring to FIGS. 15A and 15B, a second alternative configuration of the packaging structure is illustrated, which may be derived from the packaging structure illustrated in FIG. 13A-13E by modifying the pattern of the solid block portions 920 and the cavity 919. In the second alternative configuration illustrated in FIGS. 15A and 15B, the solid block portions 920 have an areal overlap with peripheral regions of the composite package 800 in the plan view. In one embodiment, the lid structure 900 may be aligned to the bonded assembly (800, 200) during attachment of the lid structure 900 to the bonded assembly (800, 200) such that the solid block portions 920 have a partial areal overlap with the frame-shaped void 939 and a partial areal overlap with the die frame 796 upon attaching the lid structure 900 to the bonded assembly (800, 200).

In one embodiment, the solid block portions 920 comprise a plurality of solid fins that laterally extend along a horizontal direction, which may be the first horizontal direction hd1 or the second horizontal direction hd2. In the illustrated example in FIGS. 15A and 15B, the plurality of solid fins of the solid block portions 920 laterally extends along the first horizontal direction hd1. In one embodiment, a first subset of the plurality of solid fins is located entirely outside areas of, i.e., does not have any areal overlap with, the composite package 800 in the plan view; and a second subset of the plurality of solid fins has a partial areal overlap with the composite package 800 in the plan view. In one embodiment, each of the solid fins may laterally extend along a lateral elongation direction (such as the first horizontal direction hd1) and may have a uniform width throughout. In one embodiment, one or more of the solid fins may have two sidewalls that are adjoined to the sidewall frame portion 910.

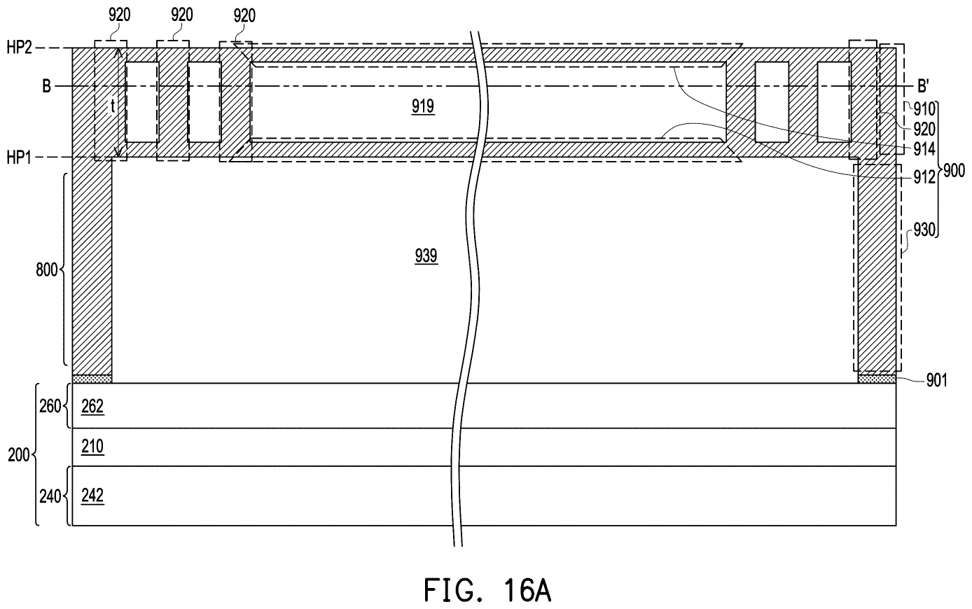

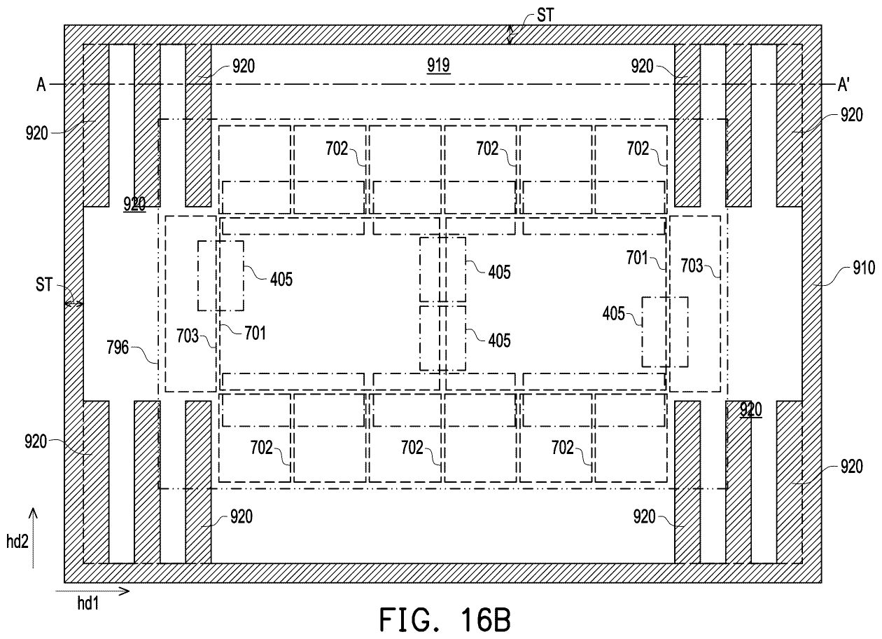

Referring to FIGS. 16A and 16B, a third alternative configuration of the packaging structure is illustrated, which may be derived from the packaging structure illustrated in FIG. 13A-13E by modifying the pattern of the solid block portions 920 and the cavity 919. In the third alternative configuration illustrated in FIGS. 16A and 16B, the solid block portions 920 have an areal overlap with peripheral regions of the composite package 800 in the plan view. In one embodiment, the lid structure 900 may be aligned to the bonded assembly (800, 200) during attachment of the lid structure 900 to the bonded assembly (800, 200) such that the solid block portions 920 have a partial areal overlap with the frame-shaped void 939 and a partial areal overlap with the die frame 796 upon attaching the lid structure 900 to the bonded assembly (800, 200).

In one embodiment, the solid block portions 920 comprise a plurality of solid fins that laterally extends along a horizontal direction, which may be the first horizontal direction hd1 or the second horizontal direction hd2. In the illustrated example in FIGS. 16A and 16B, the plurality of solid fins of the solid block portions 920 laterally extends along the second horizontal direction hd2. In one embodiment, a first subset of the plurality of solid fins is located entirely outside areas of, i.e., does not have any areal overlap with, the composite package 800 in the plan view; and a second subset of the plurality of solid fins has a partial areal overlap with the composite package 800 in the plan view. In one embodiment, each of the solid fins may laterally extend along a lateral elongation direction (such as the second horizontal direction hd1) and may have a uniform width throughout. In one embodiment, one or more of the solid fins may have two sidewalls that are adjoined to the sidewall frame portion 910.

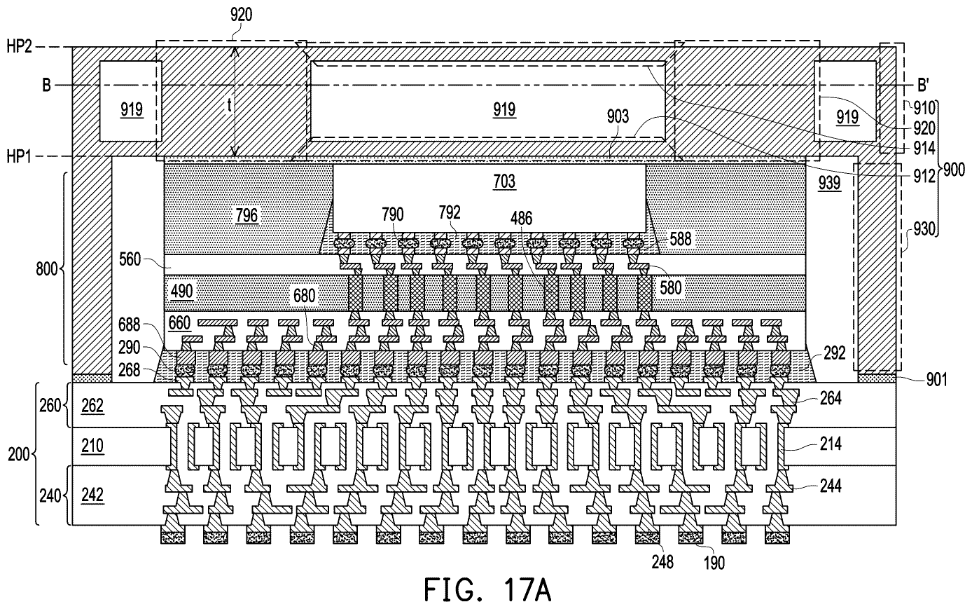

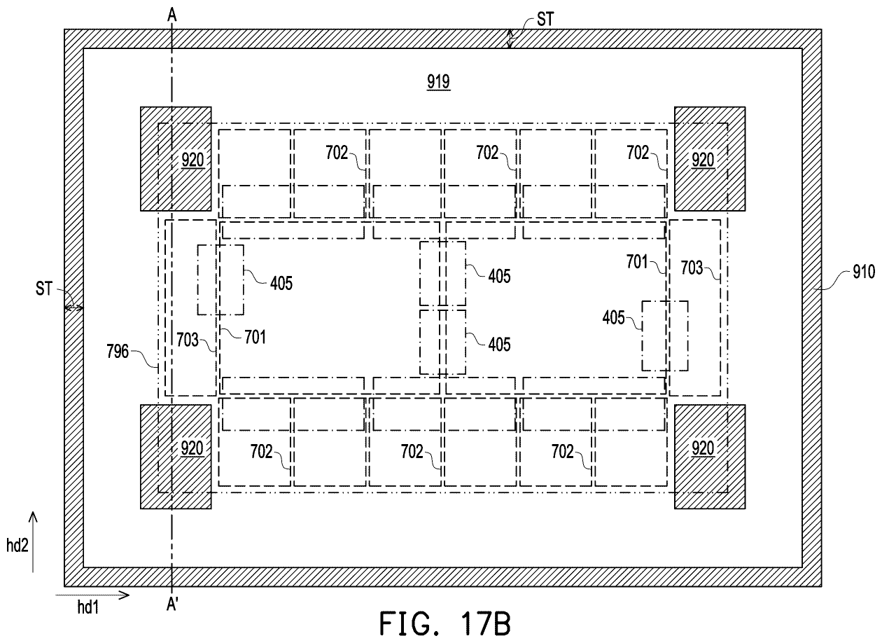

Referring to FIGS. 17A and 17B, a fourth alternative configuration of the packaging structure is illustrated, which may be derived from the packaging structure illustrated in FIG. 13A-13E by modifying the pattern of the solid block portions 920 and the cavity 919. In the fourth alternative configuration illustrated in FIGS. 17A and 17B, each of the solid block portions 920 may be detached from the sidewall frame portion 910 by a respective lateral gap, which constitutes a portion of the cavity 919. The solid block portions 920 may have an areal overlap with peripheral regions of the composite package 800 in the plan view. In this embodiment, each sidewall of the solid block portions 920 may be physically exposed to the cavity 919. In one embodiment, each solid block portion 920 may have a respective rectangular or triangular horizontal cross-sectional shape that partly overlaps with the die frame 796 without overlapping with any of the at least one semiconductor die (701, 702, 703).

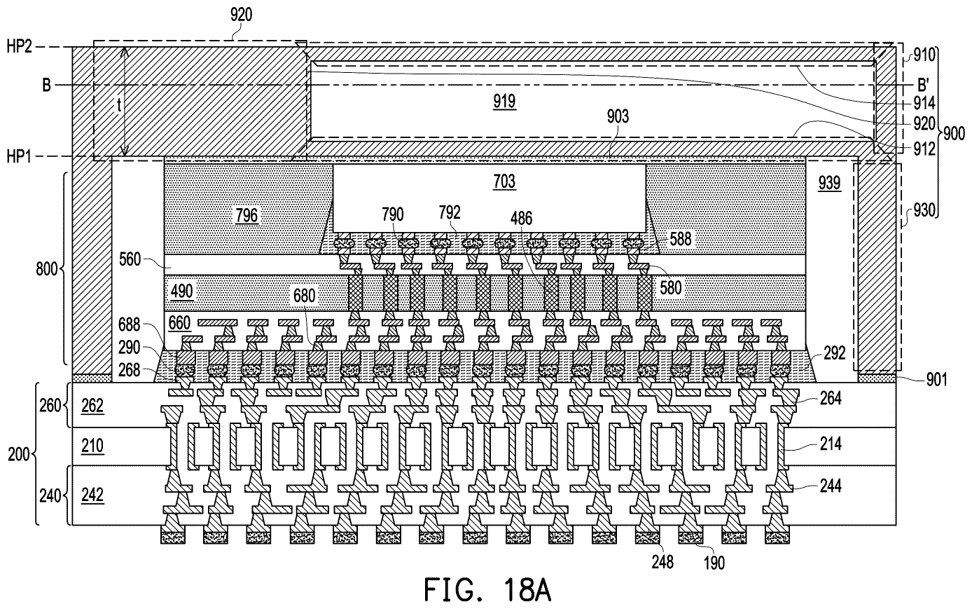

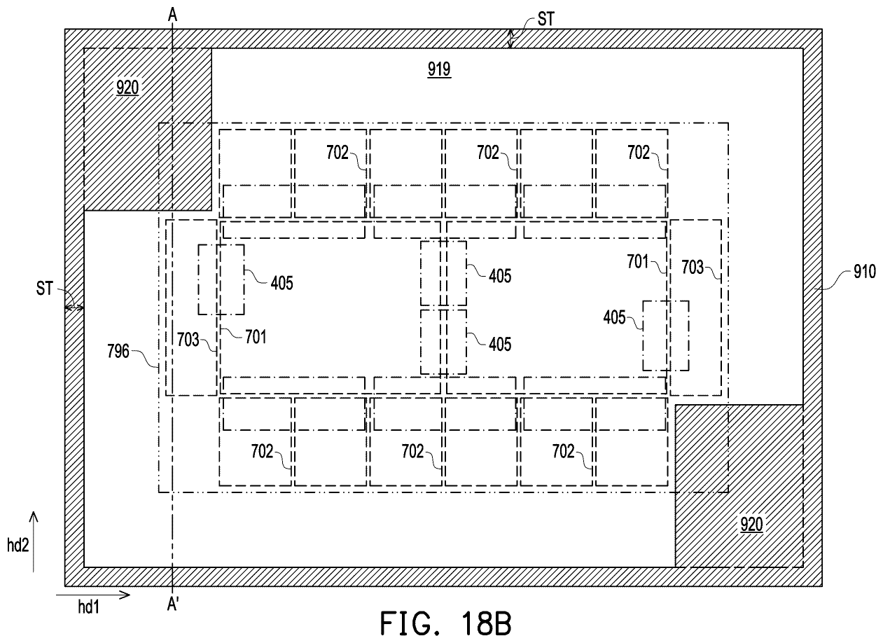

Referring to FIGS. 18A and 18B, a fifth alternative configuration of the packaging structure is illustrated, which may be derived from the packaging structure illustrated in FIG. 13A-13E, 14A and 14B, 15A and 15B, or 16A and 16B by removing at least one solid block portion 920 from at least one corner of the of the lid structure 900 without removing at least another solid block portion 920 from at least another corner of the lid structure 900. In the fifth alternative configuration, at least one solid block portion 920 is provided, which may be present in one corner region, in two corner regions, or in three corner regions. Each solid block portion 920 may, or may not, have an areal overlap with a respective peripheral region of the composite package 800 in the plan view. In one embodiment, each solid block portion 920 may have a respective rectangular or triangular horizontal cross-sectional shape, or a fin shape. Each solid block portion 920 may not overlap with, or may partly overlap with, the die frame 796. Each solid block portion 920 does not overlap with any of the at least one semiconductor die (701, 702, 703). In the illustrated example in FIGS. 18A and 18B, the solid block portions 920 are provided in two corner regions located diagonally from each other.

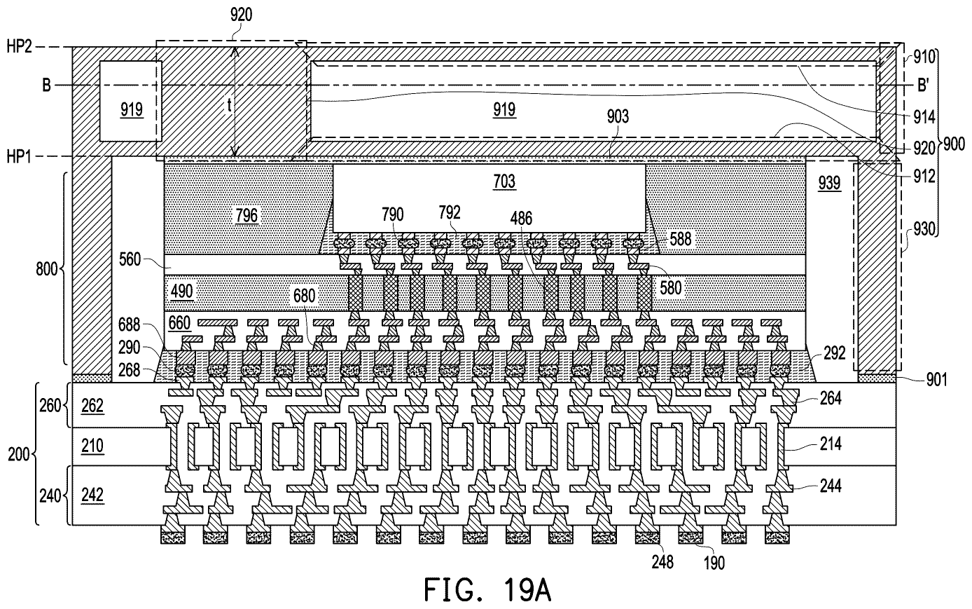

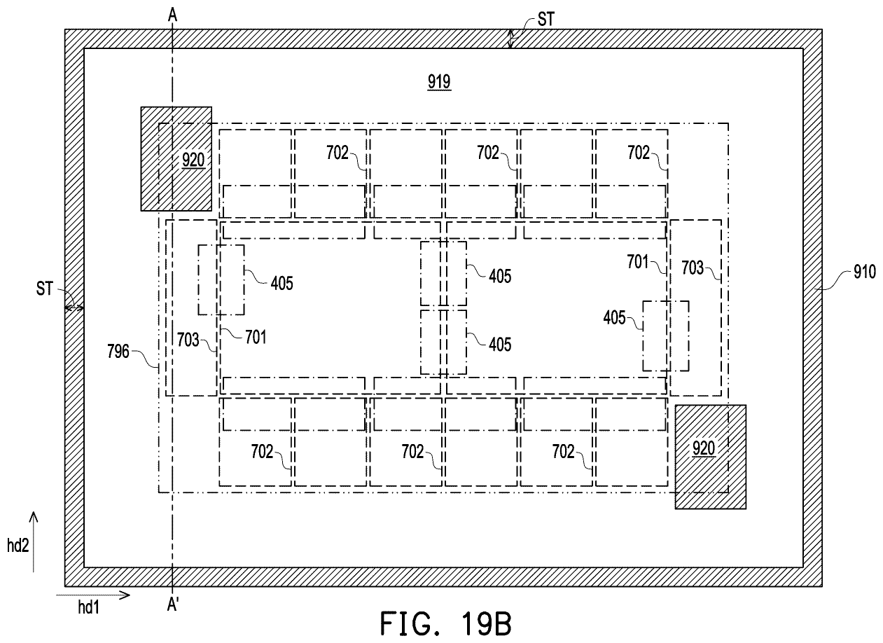

Referring to FIGS. 19A and 19B, a sixth alternative configuration of the packaging structure is illustrated, which may be derived from the packaging structure illustrated in FIGS. 17A and 17B by removing at least one solid block portion 920 from at least one corner of the of the lid structure 900 without removing at least another solid block portion 920 from at least another corner of the lid structure 900. In the fifth alternative configuration, at least one solid block portion 920 is provided, which may be present in one corner region, in two corner regions, or in three corner regions. Each solid block portion 920 may, or may not, have an areal overlap with a respective peripheral region of the composite package 800 in the plan view. In one embodiment, each solid block portion 920 may have a respective rectangular or triangular horizontal cross-sectional shape. Each solid block portion 920 may not overlap with, or may partly overlap with, the die frame 796. Each solid block portion 920 does not overlap with any of the at least one semiconductor die (701, 702, 703). In the illustrated example in FIGS. 19A and 19B, the solid block portions 920 are provided in two corner regions located diagonally from each other.

The packaging structure described with reference to FIG. 13A-13E, 14A and 14B, 15A and 15B, 16A and 16B, 17A and 17B, 18A and 18B, and 19A and 19B may be subsequently tested to determine whether the TIM layer 903 covers the entire area of the at least one semiconductor die (701, 702, 703) and/or if the TIM layer 903 contains any void or a thin region therein.

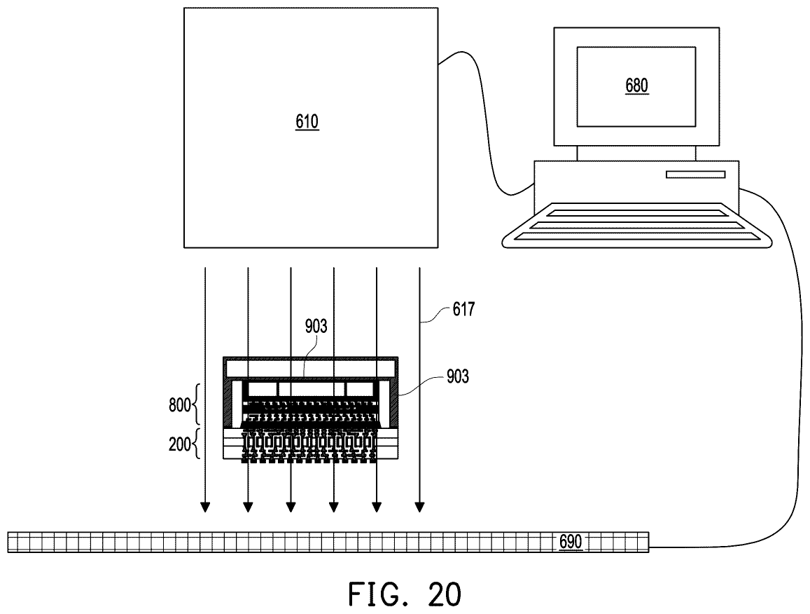

Referring to FIG. 20, an exemplary X-ray apparatus for performing a non-destructive testing on a packaging structure of the present disclosure is illustrated. The exemplary X-ray apparatus comprises an X-ray generator 610, which comprises an X-ray tube and electrical circuits for generating an X-ray beam from the X-ray tube. The exemplary X-ray apparatus further comprises an X-ray imaging transducer 690 including a two-dimensional array of X-ray sensor pixels. For example, the X-ray imaging transducer 690 may comprise a flat-panel detector, a scintillator layer coupled to a photodiode array, or a charge-coupled device (CCD) sensor array. A process controller 680 preloaded with a control program may be configured to control operation of the X-ray generator 610 and the X-ray imaging transducer 690.

As described above, a packaging structure may be formed by attaching the lid structure 900 to the bonded assembly (800, 200) such that a thermal interface material (TIM) layer 903 is interposed between the at least one semiconductor die (701, 702, 703) and the bottom plate portion 912, and the solid block portions 920 are located entirely outside areas of, i.e., do not have any areal overlap with, the at least one semiconductor die (701, 702, 703) in a plan view along a vertical direction. The TIM layer 903 may be tested for defects by generating and examining an X-ray image of the packaging structure using an X-ray beam 617 that passes through the lid structure 900, the TIM layer 903, and the bonded assembly (800, 200). Specifically, the packaging structure may be interposed between the X-ray generator 610 and the X-ray imaging transducer 690 such that the vertical direction of the packaging structure is parallel to the direction of the X-ray beam 617 that is generated from the X-ray generator 610. The X-ray imaging transducer 690 may be oriented such that the array of X-ray sensor pixels in the X-ray imaging transducer 690 is aligned within a plane that is perpendicular to the direction of the X-ray beam 617. The X-ray beam 617 is turned on such that the dose of the X-ray beam 617 may generate an X-ray image of the packaging structure such that structural features of the TIM layer 903 are displayed with optimal contrast relative to the background in the X-ray image of the packaging structure.

Generally, the TIM layer 903 may be tested for defects by generating and examining an X-ray image of the packaging structure using an X-ray beam that passes through the lid structure 900, the TIM layer 903, and the bonded assembly (800, 200). In one embodiment, the X-ray beam is directed along a vertical direction and is irradiated over an area that includes an entire area of the composite package 800 in the plan view.

Depending on the configurations of the solid block portions 920, the solid block portions 920 may be located entirely outside areas of, i.e., may not have any areal overlap with, the composite package 800 during the exposure to the X-ray beam, which is irradiated along the vertical direction of the packaging structure. In this embodiment, the solid block portions 920 does not generate any shaded area (i.e., an area blocked by portions of the lid structure 900 having the vertical thickness t), and the entire area of the composite package 800 may be examined for any abnormality in the coverage and/or thickness of the TIM layer 903.

In alternative configurations, the solid block portions 920 may have a partial areal overlap with the composite package 800. For example, the solid block portions 920 may have areal overlaps with corner portions of the die frame 796. In one embodiment, the TIM layer 903 may be formed such that the solid block portions 920 have a partial areal overlap with the TIM layer 903, and the TIM layer 903 does not cover the entirety of a top surface of the die frame 796. In some embodiments, the TIM layer 903 may cover the entirety of the top surface area(s) of the at least one semiconductor die (701, 702, 703), and may cover first areas of the top surface of the die frame 796 without covering second areas of the top surface of the die frame 796 in a plan view along the direction of the X-ray beam 617.

In embodiments in which the solid block portions 920 have a partial areal overlap with the die frame 796, areas in which the solid block portions 920 overlap with the die frame 796 may be excluded during examination of the X-ray image. Thermal contact between each semiconductor die (701, 702, 703) and the TIM layer 903 impacts the heat dissipation from the at least one semiconductor die (701, 702, 703) into the lid structure 900, while thermal contact between the die frame 796 and the TIM layer 903 is not critical for providing good thermal contact between the at least one semiconductor die (701, 702, 703) and the lid structure 900. Thus, excluding the area in which the solid block portions 920 has an areal overlap with the die frame 796 is not detrimental in providing effective examination of the TIM layer 903 for thermal contact, i.e., in determining whether the TIM layer 903 is likely to provide sufficient thermal contact between the at least one semiconductor die (701, 702, 703) and the lid structure 900.

Generally, examination of the X-ray image comprises locating any area in which a thermal interface material of the TIM layer 903 is absent or is thinner than surrounding regions. This examination may be performed by identifying any portion of the X-ray image exhibiting a higher detected X-ray dose level relative to a surrounding region. In one embodiment, examining an X-ray image comprises locating an area in which a thermal interface material of the TIM layer 903 is absent or is thinner than surrounding regions by identifying a portion of the X-ray image exhibiting a higher detected X-ray dose level relative to a surrounding region. Specifically, if the TIM layer 903 contains a void or a thinned region, such as a void or thinned region causes more X-ray photons to pass through, and the X-ray image contains a region in which more X-ray photons are detected within an area corresponding to the volumes of the void or the thinned region. Defective packaging structure having anomalies in the TIM layer 903 may be screened out through the X-ray examination.

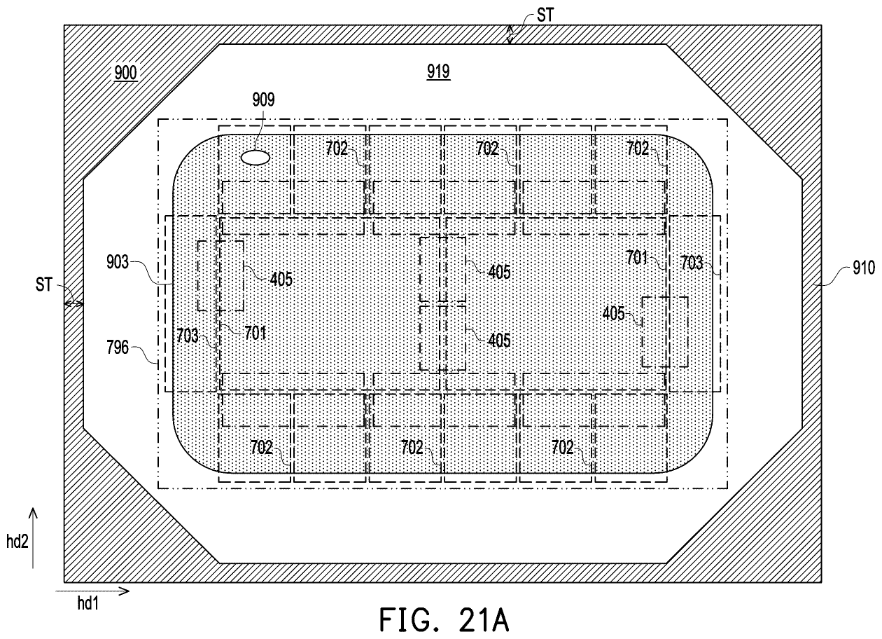

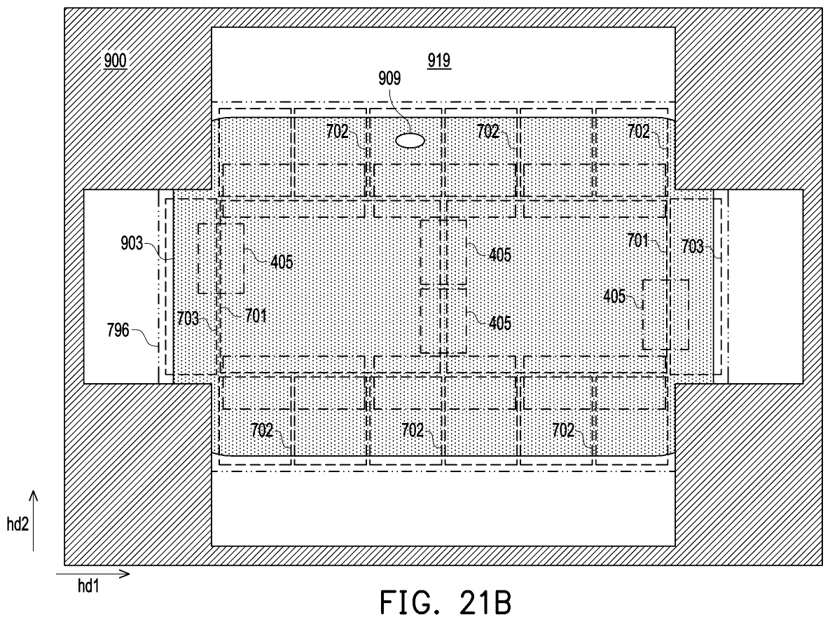

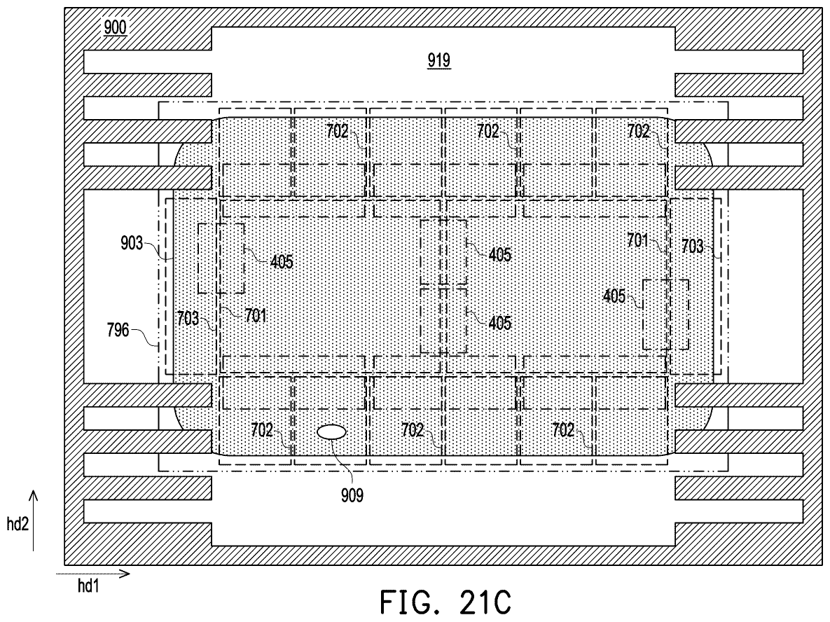

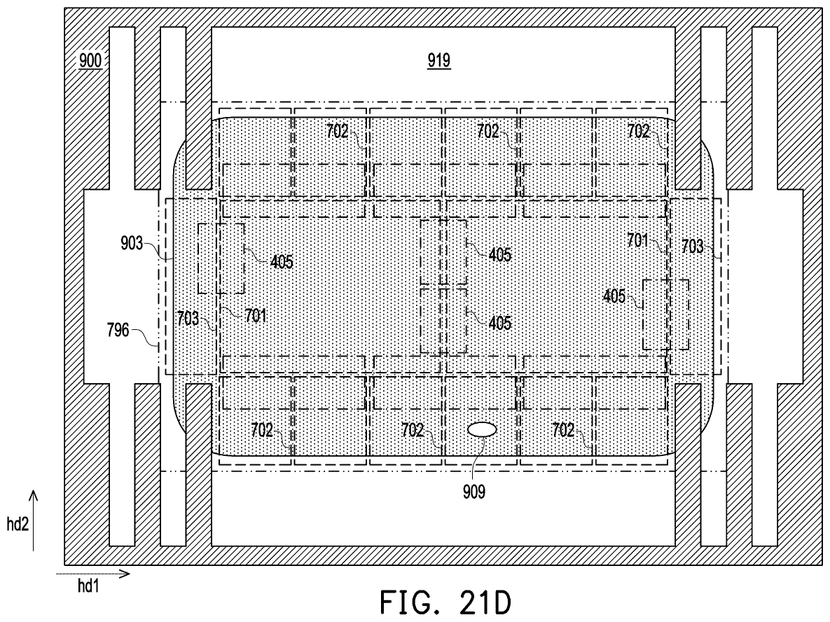

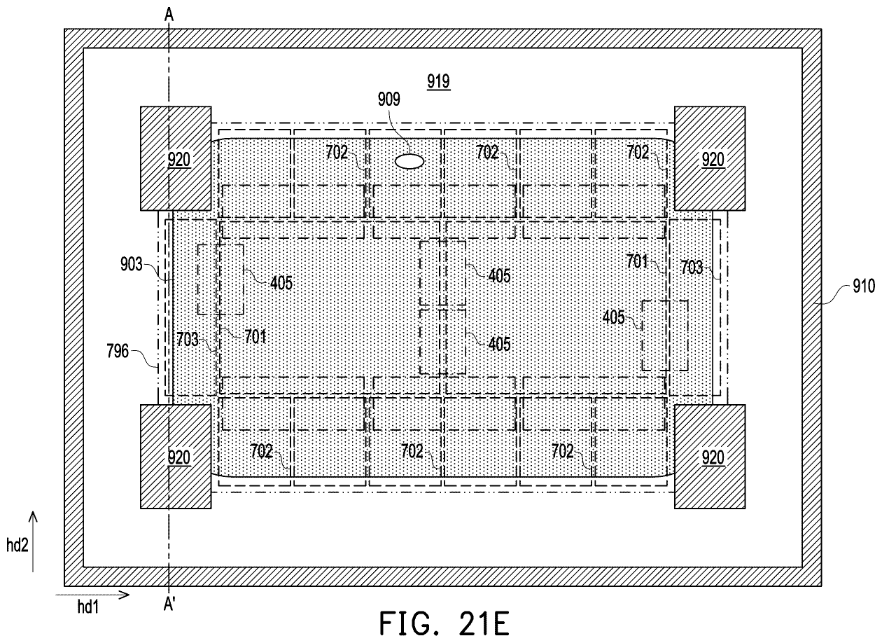

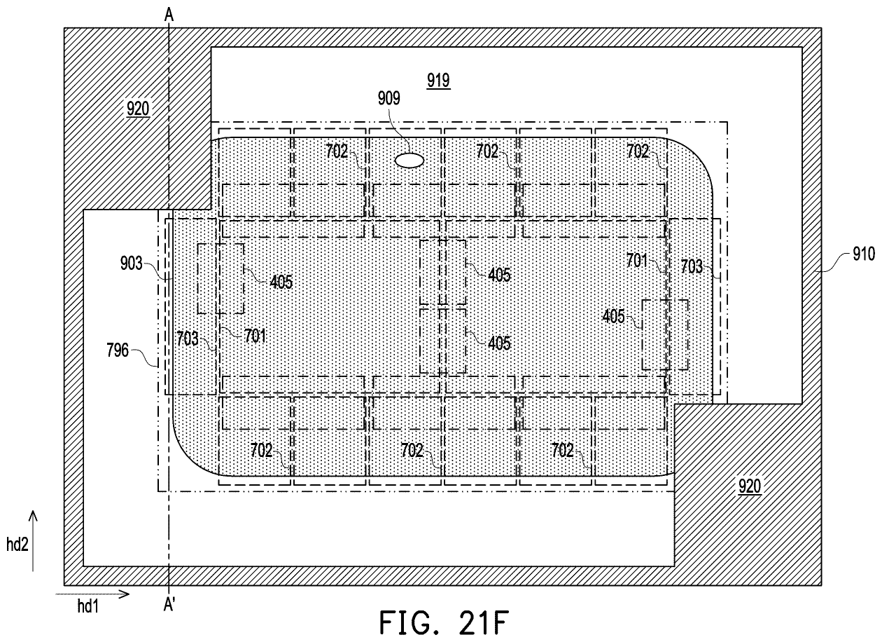

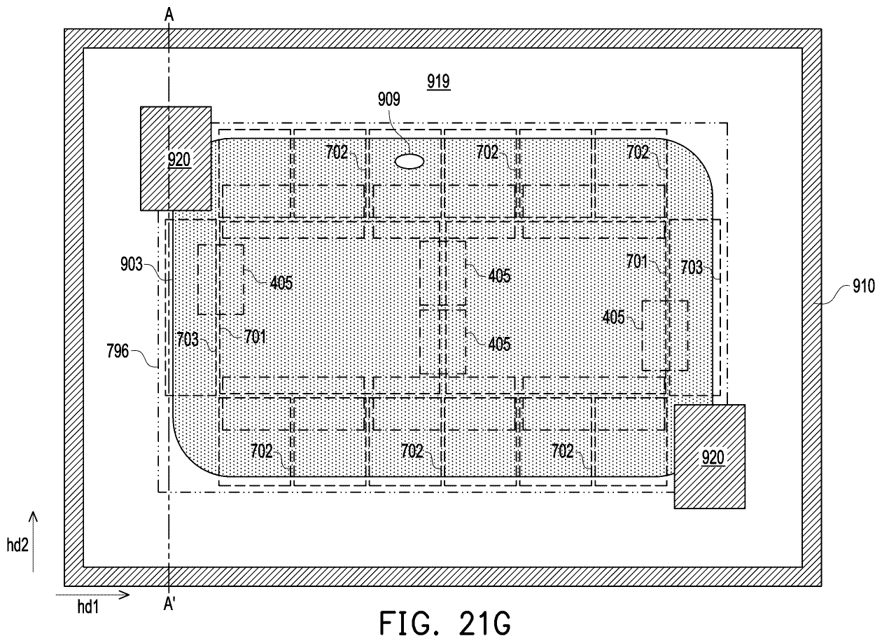

FIG. 21A-21G are schematic representations of various X-ray images that may be obtained upon testing of a packaging structure of the present disclosure. For the purpose of illustration, each of the X-ray images illustrated in FIG. 21A-21G contains an anomaly region 909 in which more X-ray photons are detected due to the presence of a void in the TIM layer 903 or due to local thinning of the TIM layer 903. The X-ray images illustrated in FIG. 21A-21G correspond to images that may be generated from the configurations of the packaging structure illustrated in FIG. 13A 13E, 14A and 14B, 15A and 15B, 16A and 16B, 17A and 17B, 18A and 18B, or 19A and 19B, respectively. The various structural elements in a corresponding package structure are labeled with corresponding reference numerals for the purpose of correlating the X-ray images in FIG. 21A-21G with the various physical structural elements in the packaging structures illustrated in FIG. 13A-13E, 14A and 14B, 15A and 15B, 16A and 16B, 17A and 17B, 18A and 18B, or 19A and 19B, respectively. It is understood that the X-ray images merely exhibit a two-dimensional distribution of detected X-ray photon densities, and the features in the X-ray images need to be correlated with the physical structures in a packaging substrate through interpretation of the images, which may be performed manually or using an image analysis program. Further, it is understood that a predominant fraction of examined packaging structures do not have any defects or anomalies in the TIM layer 903, and only a small fraction of the examined packaging structures is likely to contain any defects in the TIM layer 903.

Referring collectively to FIG. 1-21G and according to various embodiments of the present disclosure, a packaging structure is provided, which comprises: a bonded assembly (800, 200) comprising a composite package 800 and a packaging substrate 200, wherein the composite package 800 comprises at least one semiconductor die (701, 702, 703) and a die frame 796; and a lid structure 900 attached to the bonded assembly (800, 200), wherein the lid structure 900 comprises a bottom plate portion 912, a top plate portion 914 that is vertically spaced from the bottom plate portion 912, a sidewall frame portion 910 laterally surrounding a cavity 919 located between the bottom plate portion 912 and the top plate portion 914, and solid block portions 920 located within the sidewall frame portion 910 and vertically extending from a first horizontal plane HP1 including a bottom surface of the bottom plate portion 912 to a second horizontal plane HP2 including a top surface of the top plate portion 914 and located in corner regions of the lid structure 900, wherein the solid block portions 920 are located entirely outside areas of, i.e., do not have any areal overlap with, the at least one semiconductor die (701, 702, 703) in a plan view along a vertical direction. A thermal interface material (TIM) layer 903 is interposed between the at least one semiconductor die (701, 702, 703) and the bottom plate portion 912. The solid block portions 920 are located entirely outside areas of, i.e., do not have any areal overlap with, the at least one semiconductor die (701, 702, 703) in a plan view along a vertical direction.

In one embodiment, the TIM layer 903 covers the entirety of the at least one semiconductor die (701, 702, 703) in the plan view. In one embodiment, the TIM layer 903 has an areal overlap with the entirety of the at least one semiconductor die (701, 702, 703) in the plan view upon attachment of the lid structure 900 to the bonded assembly (800, 200). Generally, the TIM layer 903 coves the entirety of the top surface of each semiconductor die (701, 702, 703), if formed without defects. The TIM layer 903 may, or may not, cover the entirety of the top surface of the die frame 796 in instances in which the TIM layer 903 is formed without defects.

In one embodiment, the lid structure 900 is aligned to the bonded assembly (800, 200) during attachment of the lid structure 900 to the bonded assembly (800, 200) such that the solid block portions 920 are located entirely outside areas of, i.e., do not have any areal overlap with, the die frame 796 as described with reference to FIGS. 13A-13E.

In one embodiment, the solid block portions 920 have a partial areal overlap with the die frame 796 in the plan view as illustrated in FIG. 14A-19B. In one embodiment, the solid block portions 920 have a partial areal overlap with peripheral portions of the TIM layer 903 in the plan view. In one embodiment, the solid block portions 920 have a partial areal overlap with the frame-shaped void 939 and a partial areal overlap with the die frame 796 upon attaching the lid structure 900 to the bonded assembly (800, 200).

In one embodiment, the solid block portions 920 comprise a plurality of solid fins that laterally extend along a horizontal direction; a first subset of the plurality of solid fins is located entirely outside areas of, i.e., does not have any areal overlap with, the composite package 800 in the plan view; and a second subset of the plurality of solid fins has a partial areal overlap with the composite package 800.

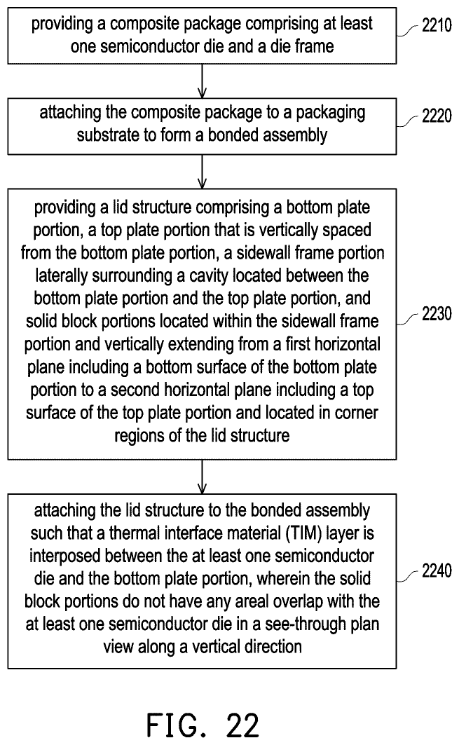

FIG. 22 is a first flowchart illustrating steps for manufacturing a packaging structure according to an embodiment of the present disclosure.

Referring to step 2210 and FIG. 1-11B, a composite package 800 comprising at least one semiconductor die (701, 702, 703) and a die frame 796 is provided.

Referring to step 2220 and FIG. 12, the composite package 800 is attached to a packaging substrate 200 to form a bonded assembly (800, 200).

Referring to step 2230 and FIG. 13A-19B, a lid structure 900 is provided, which comprises a bottom plate portion 912, a top plate portion 914 that is vertically spaced from the bottom plate portion 912, a sidewall frame portion 910 laterally surrounding a cavity 919 located between the bottom plate portion 912 and the top plate portion 914, and solid block portions 920 located within the sidewall frame portion 910 and vertically extending from a first horizontal plane HP1 including a bottom surface of the bottom plate portion 912 to a second horizontal plane HP2 including a top surface of the top plate portion 914 and located in corner regions of the lid structure 900.

Referring step 2230 and FIG. 13A-21G, the lid structure 900 may be attached to the bonded assembly (800, 200) such that a thermal interface material (TIM) layer 903 is interposed between the at least one semiconductor die (701, 702, 703) and the bottom plate portion 912, wherein the solid block portions 920 are located entirely outside areas of, i.e., do not have any areal overlap with, the at least one semiconductor die (701, 702, 703) in a plan view along a vertical direction. It is understood that the plan view displays all structural elements irrespective of coverage by any overlying structural element. Thus, the plan views as employed in this disclosure are see-through plan views.

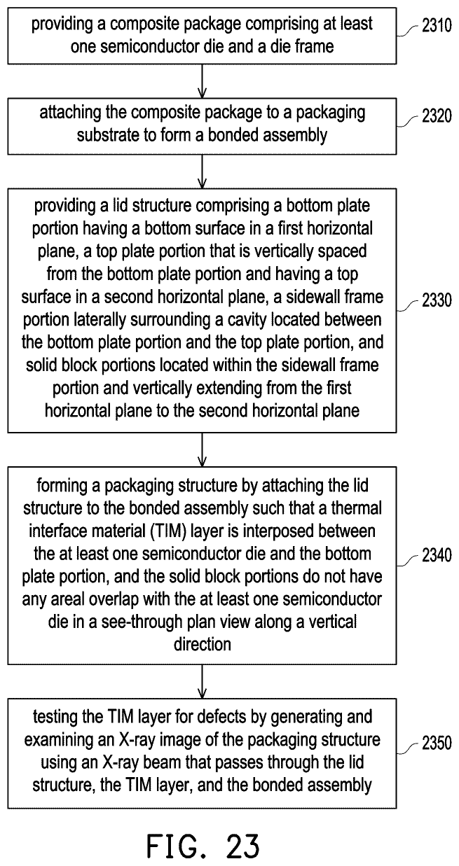

FIG. 23 is a second flowchart illustrating steps for manufacturing a packaging structure according to an embodiment of the present disclosure.

Referring to step 2310 and FIG. 1-11B, a composite package 800 comprising at least one semiconductor die (701, 702, 703) and a die frame 796 is provided.

Referring to step 2320 and FIG. 12, the composite package 800 may be attached to a packaging substrate 200 to form a bonded assembly (800, 200).

Referring to step 2330 and FIG. 13A-19B, a lid structure 900 is provided, which comprises a bottom plate portion 912 having a bottom surface in a first horizontal plane HP1, a top plate portion 914 that is vertically spaced from the bottom plate portion 912 and having a top surface in a second horizontal plane HP2, a sidewall frame portion 910 laterally surrounding a cavity 919 located between the bottom plate portion 912 and the top plate portion 914, and solid block portions 920 located within the sidewall frame portion 910 and vertically extending from the first horizontal plane HP1 to the second horizontal plane HP2.

Referring step 2340 and FIG. 13A-19B, a packaging structure may be formed by attaching the lid structure 900 to the bonded assembly (800, 200) such that a thermal interface material (TIM) layer 903 is interposed between the at least one semiconductor die (701, 702, 703) and the bottom plate portion 912, and the solid block portions 920 are located entirely outside areas of, i.e., do not have any areal overlap with, the at least one semiconductor die (701, 702, 703) in a plan view along a vertical direction. It is understood that the plan view displays all structural elements irrespective of coverage by any overlying structural element.

Referring to step 2350 and FIG. 20-21G, the TIM layer 903 may be tested for defects by generating and examining an X-ray image of the packaging structure using an X-ray beam that passes through the lid structure 900, the TIM layer 903, and the bonded assembly (800, 200).

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a packaging structure, the method comprising:
providing a composite package comprising at least one semiconductor die and a die frame;
attaching the composite package to a packaging substrate to form a bonded assembly;
providing a lid structure comprising a bottom plate portion, a top plate portion that is vertically spaced from the bottom plate portion, a sidewall frame portion laterally surrounding a cavity located between the bottom plate portion and the top plate portion, and solid block portions located within the sidewall frame portion and vertically extending from a first horizontal plane including a bottom surface of the bottom plate portion to a second horizontal plane including a top surface of the top plate portion and located in corner regions of the lid structure; and
attaching the lid structure to the bonded assembly such that a thermal interface material (TIM) layer is interposed between the at least one semiconductor die and the bottom plate portion, wherein the solid block portions are located entirely outside of areas of the at least one semiconductor die in a plan view along a vertical direction.

2. The method of claim 1, wherein the TIM layer has an areal overlap with an entirety of the at least one semiconductor die in the plan view upon attachment of the lid structure to the bonded assembly.

3. The method of claim 1, wherein the lid structure is aligned to the bonded assembly during attachment of the lid structure to the bonded assembly such that the solid block portions do not have any areal overlap with the die frame.

4. The method of claim 1, wherein the TIM layer is formed by application of a thermal interface material to each top surface of the at least one semiconductor die or to a bottom surface of the bottom plate portion, and by pressing the thermal interface material between the at least one semiconductor die and the lid structure.

5. The method of claim 1, wherein:
the lid structure further comprises an enclosure wall portion extending downward from a peripheral region of the bottom plate portion; and
attaching the lid structure to the bonded assembly comprises attaching the enclosure wall portion to the packaging substrate.

6. The method of claim 5, wherein:
the enclosure wall portion is attached to a frame-shaped surface segment of a top surface of the packaging substrate through an adhesive layer; and
the enclosure wall portion laterally surrounds the composite package.

7. The method of claim 5, wherein:
attaching the lid structure to the bonded assembly to form a frame-shaped void around the composite package between sidewalls of the composite package and inner sidewalls of the enclosure wall portion; and
the solid block portions are located outside an area of the composite package in the plan view.

8. The method of claim 5, wherein:
attaching the lid structure to the bonded assembly forms a frame-shaped void around the composite package between sidewalls of the composite package and inner sidewalls of the enclosure wall portion; and
the solid block portions have a partial areal overlap with the frame-shaped void and a partial areal overlap with the die frame upon attaching the lid structure to the bonded assembly.

9. The method of claim 1, wherein:
the solid block portions comprise a plurality of solid fins that laterally extend along a horizontal direction;
a first subset of the plurality of solid fins does not have any areal overlap with the composite package in the plan view; and
a second subset of the plurality of solid fins has a partial areal overlap with the composite package.

10. The method of claim 1, further comprising testing the TIM layer for defects by generating and examining an X-ray image of the packaging structure using an X-ray beam that passes through the lid structure, the TIM layer, and the bonded assembly.

11. A method of manufacturing a packaging structure, the method comprising:
providing a composite package comprising at least one semiconductor die and a die frame;
attaching the composite package to a packaging substrate to form a bonded assembly;
providing a lid structure comprising a bottom plate portion having a bottom surface in a first horizontal plane, a top plate portion that is vertically spaced from the bottom plate portion and having a top surface in a second horizontal plane, a sidewall frame portion laterally surrounding a cavity located between the bottom plate portion and the top plate portion, and solid block portions located within the sidewall frame portion and vertically extending from the first horizontal plane to the second horizontal plane; and
forming a packaging structure by attaching the lid structure to the bonded assembly such that a thermal interface material (TIM) layer is interposed between the at least one semiconductor die and the bottom plate portion, and the solid block portions are located entirely outside areas of the at least one semiconductor die in a plan view along a vertical direction.

12. The method of claim 11, further comprising testing the TIM layer for defects by generating and examining an X-ray image of the packaging structure using an X-ray beam that passes through the lid structure, the TIM layer, and the bonded assembly.

13. The method of claim 12, wherein the X-ray beam is directed along a vertical direction and is irradiated over an area that includes an entire area of the composite package in the plan view.

14. The method of claim 12, wherein examining an X-ray image comprises locating an area in which a thermal interface material of the TIM layer is absent or is thinner than surrounding regions by identifying a portion of the X-ray image exhibiting a higher detected X-ray dose level relative to a surrounding region.

15. The method of claim 11, wherein:
the solid block portions have a partial areal overlap with the die frame; and
the method comprises excluding areas in which the solid block portions overlap with the die frame during examination of the X-ray image.

16. A packaging structure comprising:
a bonded assembly comprising a composite package and a packaging substrate, wherein the composite package comprises at least one semiconductor die and a die frame; and
a lid structure attached to the bonded assembly, wherein the lid structure comprises a bottom plate portion, a top plate portion that is vertically spaced from the bottom plate portion, a sidewall frame portion laterally surrounding a cavity located between the bottom plate portion and the top plate portion, and solid block portions located within the sidewall frame portion and vertically extending from a first horizontal plane including a bottom surface of the bottom plate portion to a second horizontal plane including a top surface of the top plate portion and located in corner regions of the lid structure, wherein the solid block portions are located entirely outside areas of the at least one semiconductor die in a plan view along a vertical direction.

17. The packaging structure of claim 16, further comprising a thermal interface material (TIM) layer located between the at least one semiconductor die and the bottom plate portion, wherein the TIM layer covers an entirety of the at least one semiconductor die in the plan view.

18. The packaging structure of claim 16, wherein the solid block portions are located entirely outside areas of the composite package in the plan view.

19. The packaging structure of claim 16, wherein the solid block portions have a partial areal overlap with the die frame in the plan view.

20. The packaging structure of claim 16, wherein the solid block portions have a partial areal overlap with peripheral portions of the TIM layer in the plan view.
